(19) United States
(12) Patent Application Publication
(10) Pub. No.: US 2026/0059885 A1
(43) Pub. Date: Feb. 26, 2026

(54) IMAGE SENSOR DEVICE AND METHODS OF FORMATION

(71) Applicant: Taiwan Semiconductor Manufacturing Company, Ltd, Hsinchu (TW)

(72) Inventors: Kuan-Fu LU, Tainan City (TW); Feng-Chi HUNG, Chu-Bei City (TW); Jen-Cheng LIU, Hsin-Chu City (TW); Shyh-Fann TING, Tainan City (TW); Wen-I HSU, Tainan City (TW)

(21) Appl. No.: 18/812,189

(22) Filed: Aug. 22, 2024

(51) Int. Cl. H01L 27/146

(52) U.S. Cl. CPC H10F 39/811; H10F 39/026; H10F 39/80373

(57) ABSTRACT

A semiconductor die of an image sensor device includes a doped well region in a substrate layer of the semiconductor die. The doped well region may be included adjacent to an elongated conductive structure that extends vertically through the substrate layer into interconnect layers on opposing sides of the substrate layer. The doped well region introduces additional series capacitance between the elongated conductive structure and the substrate layer (which may be formed of one or more semiconductor materials). This additional series capacitance, which is electrically connected in series with parasitic capacitance associated with the elongated conductive structure, effectively reduces the overall parasitic capacitance in the control circuitry of the pixel sensors of the image sensor device.

### BACKGROUND

A complementary metal oxide semiconductor (CMOS) image sensor may include a plurality of pixel sensors arranged in a pixel sensor array. A pixel sensor of the CMOS image sensor may include a photodiode configured to convert photons of incident light to a photocurrent of electrons. The magnitude of the photocurrent is based at least in part on the intensity of the incident light.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A and 2B are diagrams of an example semiconductor die package described herein.

FIGS. 3A-3E are diagrams of an example implementation of forming a semiconductor die (or a portion thereof) described herein.

FIGS. 4A-4D are diagrams of an example implementation of forming a semiconductor die (or a portion thereof) described herein.

FIGS. 5A-5D are diagrams of an example implementation of forming a semiconductor die package (or a portion thereof) described herein.

FIGS. 6A and 6B are diagrams of an example implementation of forming a semiconductor die package (or a portion thereof) described herein.

FIGS. 7A-7D are diagrams of an example implementation of forming a semiconductor die (or a portion thereof) described herein.

FIGS. 8A-8D are diagrams of an example implementation of forming a semiconductor die package (or a portion thereof) described herein.

FIGS. 9A-9D are diagrams of an example implementation of forming a semiconductor die package (or a portion thereof) described herein.

FIG. 10 is a flowchart of an example process associated with forming an image sensor device described herein.

FIG. 11 is a flowchart of an example process associated with forming an image sensor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A complementary metal oxide semiconductor (CMOS) image sensor device may include a plurality of semiconductor dies that are bonded together in a vertical stack. A sensor die in the vertical stack may include photodiodes (e.g., the sensing regions) of a plurality of pixel sensors arranged in a pixel sensor array. The control circuitry of the pixel sensors (e.g., transfer gates, reset gates, source-follower gates, row-select gates) may be distributed across the sensor die and an application-specific integrated circuit (ASIC) die bonded to the sensor die in the vertical stack. An image processing die may be bonded to the ASIC die in the vertical stack, and thus the CMOS image sensor device may be referred to as a three-dimensional (3D) CMOS image sensor or 3D CIS.

The photodiodes and associated control circuitry of the pixel sensors may be interconnected through various interconnect layers of the semiconductor dies in the vertical stack. While this enables the functionality of the pixel sensors to be distributed across the vertical stack (which provides a greater amount of lateral area for the pixel sensors and, thus, enables a greater lateral density of pixel sensors to be included in the CMOS image sensor device), the interconnect layers may introduce drawbacks that negatively affect the performance of the pixel sensors.

One drawback is parasitic capacitance. The interconnect layers of the semiconductor dies include electrically conductive structures. If those conductive structures are positioned too closely together, and/or positioned too closely to other conductive or semiconductive structures or regions in the semiconductor dies, unwanted parasitic capacitance can occur. The parasitic capacitance may negative affect the performance of the pixel sensors by increasing resistance-capacitance (RC) delay in the control circuitry of the pixel sensors. The increased RC delay can increase the processing time for the photocurrents generated by the pixel sensors, resulting in reduced responsiveness for the pixel sensor array. This can result in degraded high-speed imaging performance (e.g., can result in blurred images and reduced motion tracking performance) and/or can result in degraded low-light performance. Additionally and/or alternatively, this can result in increased power consumption and reduced dynamic range (e.g., due to signal loss from the parasitic capacitance), among other examples.

In some implementations described herein, a semiconductor die (e.g., an ASIC die) of an image sensor device (e.g., a CMOS image sensor device) includes a doped well region in a substrate layer of the semiconductor die. The doped well region may be included adjacent to an elongated conductive structure that extends vertically through the substrate layer into interconnect layers on opposing sides of the substrate layer. The doped well region introduces additional series capacitance between the elongated conductive structure and the substrate layer (which may be formed of one or more semiconductor materials). This additional series capacitance, which is electrically connected in series with parasitic capacitance associated with the elongated conductive structure, effectively reduces the overall parasitic capacitance in the control circuitry of the pixel sensors of the image sensor device. In this way, the reduced parasitic capacitance may enable a low RC delay to be achieved for the pixel sensors, which may increase the responsiveness of the pixel sensors. The increased responsiveness may increase the high-speed imaging performance and/or the low-light performance of the image sensor device, may increase the dynamic range of the image sensor device, and/or may reduce the power consumption of the image sensor device, among other examples.

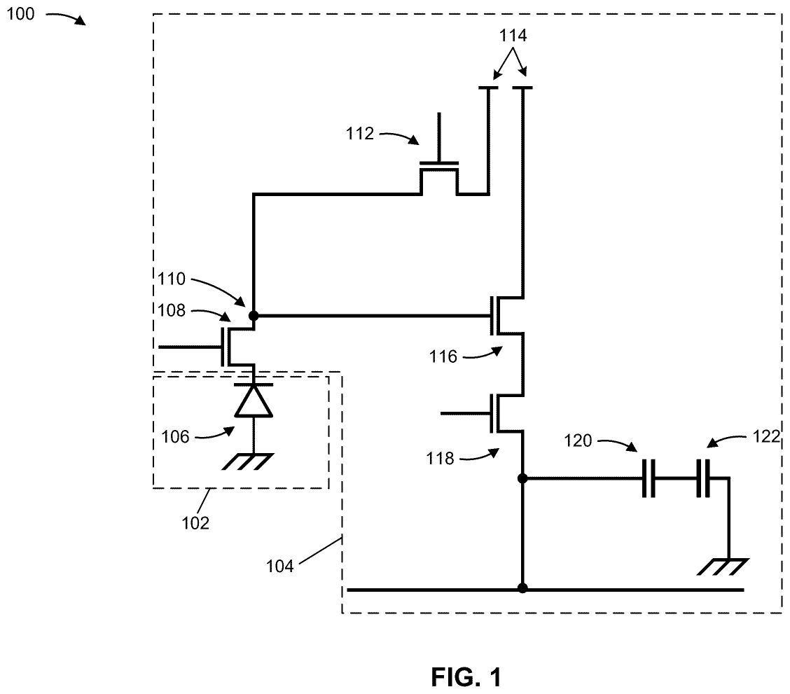

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

The pixel sensor 100 includes a sensing region 102 that may be configured to sense and/or accumulate incident light (e.g., light directed toward the pixel sensor 100). The pixel sensor 100 also includes a control circuitry region 104. The control circuitry region 104 is electrically connected with the sensing region 102 and is configured to receive a photocurrent that is generated by the sensing region 102. Moreover, the control circuitry region 104 is configured to transfer the photocurrent from the sensing region 102 to downstream circuits such as image processing circuits, among other examples.

The sensing region 102 includes a photodiode 106. The photodiode 106 may absorb and accumulate photons of the incident light, and may generate the photocurrent based on absorbed photons. The magnitude of the photocurrent is based on the amount of light collected in the photodiode 106. Thus, the accumulation of photons in the photodiode 106 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 106 is electrically connected with a source/drain of a transfer gate 108 of the control circuitry region 104. The transfer gate 108 is configured to control the transfer of the photocurrent from the photodiode 106 to a floating diffusion node 110. The photocurrent is provided from a source/drain (e.g., which may correspond to the photodiode 106) of the transfer gate 108 to another drain/drain of the transfer gate 108 (e.g., which may correspond to the floating diffusion node 110) based on selectively switching a gate of the transfer gate 108. The gate of the transfer gate 108 may be selectively switched by applying a transfer voltage (Vₜₓ) to the transfer gate 108. In some implementations, the transfer voltage being applied to the transfer gate 108 causes a conductive channel (e.g., a leakage path or buried channel) to form between the photodiode 106 and the floating diffusion node 110, which enables the photocurrent to propagate through the conductive channel from the photodiode 106 to the floating diffusion node 110. In some implementations, the transfer voltage being removed from the transfer gate 108 (or the absence of the transfer voltage) causes the conductive channel to be removed such that the photocurrent cannot pass from the photodiode 106 to the floating diffusion node 110.

The control circuitry region 104 further includes a reset gate 112. The reset gate 112 is electrically connected to a supply voltage 114. The reset gate 112 may be controlled by a reset voltage (Vᵣₛₜ) applied by the supply voltage 114. The reset gate 112 may be electrically coupled with the floating diffusion node 110. The reset voltage may be applied to the reset gate 112 to pull the floating diffusion node 110 to a high voltage (e.g., to the supply voltage) to “reset” the floating diffusion node 110 (e.g., by draining any residual charge in the floating diffusion node 110) prior to activation of the transfer gate 108 to transfer the photocurrent from the photodiode 106 to the floating diffusion node 110.

The photocurrent may be used to apply a floating diffusion voltage (V_{fd}) to a source-follower gate 116 of the control circuitry region 104. This permits the photocurrent to be observed without removing or discharging the photocurrent from the floating diffusion node 110. The reset gate 112 may instead be used to remove or discharge the photocurrent from the floating diffusion node 110.

The source-follower gate 116 functions as a high impedance amplifier for the pixel sensor 100. The source-follower gate 116 provides a voltage to current conversion of the floating diffusion voltage. The output of the source-follower gate 116 is electrically connected with a row-select gate 118, which is configured to control the flow of the photocurrent to external circuitry. The row-select gate 118 is controlled by selectively applying a select voltage (V_{di}) to the gate of the row-select gate 118. This permits the photocurrent to flow to an output of the pixel sensor 100.

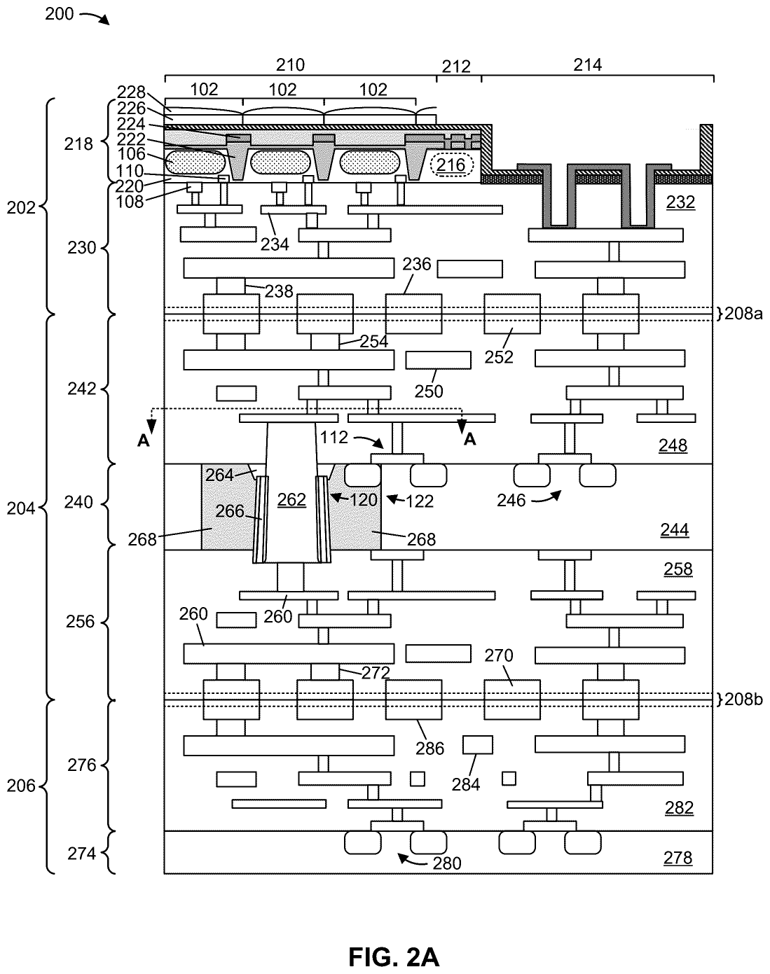

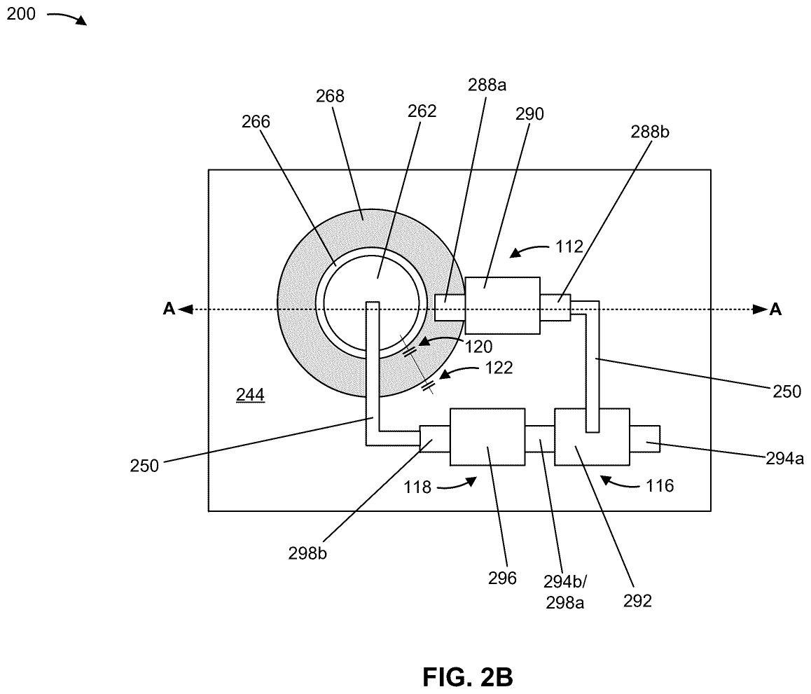

As further shown in FIG. 1, various sources of capacitance (e.g., parasitic capacitance) may be present in the control circuitry region 104 of the pixel sensor 100. For example, a capacitor 120 may introduce parasitic capacitance into the control circuitry region 104 of the pixel sensor 100, where the parasitic capacitance is associated with an elongated conductive structure (e.g., a through substrate via (TSV)) that extends through a substrate layer of a semiconductor die in which the reset gate 112, the source-follower gate 116, and the row-select gate 118 may be included. As another example, a capacitor 122 may introduce parasitic capacitance into the control circuitry region 104 of the pixel sensor 100, where the parasitic capacitance is associated with a doped well region near the elongated conductive structure. As described in connection with FIGS. 2A and 2B, the doped well region is included in the substrate layer of the semiconductor die between the elongated conductive structure and the reset gate 112 to add series capacitance with the parasitic capacitance of the capacitor 120. The capacitance of the capacitor 122 may be less than the capacitance of the capacitor 120. The lower capacitance, combined with the series connection between the capacitors 120 and 122, results in a reduction in the overall capacitance of the control circuitry region 104 of the pixel sensor 100. The overall capacitance of the control circuitry region 104 of the pixel sensor 100 may be represented as:

$${C}_{pix} = {C}_{total} + {C}_{TSV} * {C}_{j} / {C}_{TSV} + {C}_{j} ,$$

where Cₚᵢₓ is the overall capacitance of the control circuitry region 104 of the pixel sensor 100, Cₜₒₜₐₗ is the capacitance in the interconnects between components of the pixel sensor 100, C_{TSV} is the parasitic capacitance of the elongated conductive structure, and Cⱼ is the lower parasitic capacitance introduced by the doped well region. As indicated above, FIG. 1 is provided as an example. Other examples may differ from what is described with regard to FIG. 1.

FIGS. 2A and 2B are diagrams of an example semiconductor die package 200 described herein. FIG. 2A illustrates a cross-section view of the semiconductor die package 200. FIG. 2B illustrates a top view of a portion of the semiconductor die package 200 at the location of the line A-A in FIG. 2A. The semiconductor die package 200 includes an image sensor device such as a CMOS image sensor device that includes one or more pixel sensors 100.

As shown in FIG. 2A, the semiconductor die package 200 includes a plurality of semiconductor dies, including a semiconductor die 202, a semiconductor die 204, and a semiconductor die 206, among other examples. Other quantities of semiconductor dies for the semiconductor die package 200 are within the scope of the present disclosure.

The semiconductor dies 202-206 may be vertically stacked or vertically arranged in the semiconductor die package 200. For example, the semiconductor die 202 and the semiconductor die 204 may be bonded at a bonding interface 208a such that the semiconductor dies 202 and 204 are stacked and vertically arranged in the semiconductor die package 200. As another example, the semiconductor die 204 and the semiconductor die 206 may be bonded at a bonding interface 208b such that the semiconductor dies 204 and 206 are stacked and vertically arranged in the semiconductor die package 200. The bond between the semiconductor dies 202 and 204, and the bond between the semiconductor dies 204 and 206, may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 202 and 204 by forming metal-to-metal bonds and/or dielectric-to-dielectric bonds at the bonding interface 208a between the semiconductor dies 202 and 204. A bonding tool may be used to perform a bonding operation to bond the semiconductor dies 204 and 206 by forming metal-to-metal bonds and/or dielectric-to-dielectric bonds at the bonding interface 208b between the semiconductor dies 204 and 206.

The semiconductor die 202 may be an image sensor die of the semiconductor die package 200. The semiconductor die package 200 may be configured to generate images and/or video based on sensing performed by the semiconductor die 202. Thus, the semiconductor die package 200 may be a three-dimensional (3D) CMOS image sensor (3D CIS) because of the vertical arrangement of the semiconductor dies 202-206.

As shown in FIG. 2A, the semiconductor die 202 may include a pixel sensor array 210, a black level correction (BLC) region 212 adjacent to (e.g., horizontally adjacent to) the pixel sensor array 210, and a bonding pad region 214 adjacent to (e.g., horizontally adjacent to) the BLC region 212, among other examples. In some implementations, the semiconductor die 202 includes additional lateral regions, such as a seal ring region and/or a scribe line region, among other examples. The pixel sensor array 210 includes a plurality of sensing regions 102 of a plurality of pixel sensors 100. The sensing regions 102 of the pixel sensors 100 may be arranged in a grid or in another type of arrangement, and may be configured to generate photocurrents based on photons of incident light. The BLC region 212 may include a region 216 in a device layer 218 of the semiconductor die 202 that is shielded from incident light by a metal shielding layer. The metal shielding layer may be included as a light-blocking layer to prevent incident light from entering the region 216. The region 216 is thus a sensing region that is kept “dark” so that dark current measurements may be performed in the BLC region 212. A dark current measurement may be performed to measure the amount of charge (dark current) in the device layer 218 that is generated from sources other than incident light (e.g., from thermal energy in the device layer 218) so that the dark current measurement may be used for black level correction (or black level calibration) for the pixel sensor array 210. The bonding pad region 214 may include a bonding pad structure that enables an external electrical connection to be formed to the semiconductor die package 200.

The device layer 218 includes a substrate layer 220. The substrate layer 220 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material.

Photodiodes 106 of the sensing regions 102 of the pixel sensors 100 are included in the substrate layer 220 of the semiconductor die 202. The photodiodes 106 may each include one or more doped regions of substrate layer 220. The substrate layer 220 may be doped with a plurality of types of ions to form a p-n junction or a PIN junction (e.g., a junction between a p-type portion, an intrinsic (or undoped) type portion, and an n-type portion) corresponding to a photodiode 106. For example, the substrate layer 220 may be doped with an n-type dopant to form a first portion (e.g., an n-type portion) of a photodiode 106 and a p-type dopant to form a second portion (e.g., a p-type portion) of the photodiode 106. A photodiode 106 may be configured to absorb photons of incident light. The absorption of photons causes the photodiode 106 to accumulate a charge (a photocurrent) due to the photoelectric effect. Here, photons bombard the photodiode 106, which causes emission of electrons of the photodiode 106. The emission of electrons causes the formation of electron-hole pairs, where the electrons migrate toward the cathode of the photodiode 106 and the holes migrate toward the anode, which produces the photocurrent.

The photodiodes 106 may be electrically isolated and/or optically isolated from one another by one or more isolation structures in the substrate layer 220. For example, a deep trench isolation (DTI) structure 222 may extend into the substrate layer 220 from a backside of the substrate layer 220. The DTI structure 222 may include elongated structures that include a one or more dielectric layers, one or more metal layers, and/or another arrangement of layers and/or materials. The DTI structure 222 may laterally surround the photodiodes 106 of the pixel sensors 100 in the substrate layer 220.

A metal grid structure 224 may be included above the backside of the substrate layer 220. Sections of the metal grid structure 224 may be located over the DTI structure 222 and may be formed around the perimeter of the photodiodes 106 of the sensing regions 102 of the pixel sensors 100. Openings in the metal grid structure 224 are included above the photodiodes 106 to enable incident light to pass through the metal grid structure 224 and to the photodiodes 106. The metal grid structure 224 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Color filter regions 226 of the sensing regions 102 of the pixel sensors 100 be included in the openings in the metal grid structure 224. The color filter regions 226 may be included above the photodiodes 106 of the sensing regions 102 of the pixel sensors 100. The color filter regions 226 may be included above the photodiodes 106. Each color filter region 226 may be configured to filter incident light to allow a particular wavelength of the incident light to pass to a photodiode 106. For example, a color filter region 226 may filter incident light to allow red light to pass through the color filter region 226 to an associated photodiode 106. As another example, a color filter region 226 may filter incident light to allow green light to pass through the color filter region 226 to an associated photodiode 106. As another example, a color filter region 226 may filter incident light to allow blue light to pass through the color filter region 226 to an associated photodiode 106. In some implementations, a color filter region 226 may be non-discriminating or non-filtering, which may define a white pixel sensor. A non-discriminating or non-filtering color filter region 226 may include a material that permits all wavelengths of light to pass into the associated photodiode 106 (e.g., for purposes of determining overall brightness to increase light sensitivity for the image sensor). In some implementations, a color filter region 226 may be a near infrared (NIR) bandpass color filter region 226, which may define an NIR pixel sensor. An NIR bandpass color filter region 228 may include a material that permits the portion of incident light in an NIR wavelength range to pass to an associated photodiode 106 while blocking visible light from passing.

Micro-lenses 228 may be included over and/or on the color filter regions 226. The micro-lenses 228 may include a respective micro-lens for each of the sensing regions 102 of the pixel sensors 100. A micro-lens 228 may be formed to focus incident light toward a photodiode 106 of a sensing region 102 of a pixel sensor 100.

Transfer gates 108 of the pixel sensors 100 are included on the frontside of the substrate layer 220. The transfer gates 108 are configured to selectively control the flow of photocurrents from the photodiodes 106 to floating diffusion nodes 110 of the pixel sensors 100. The floating diffusion nodes 110 may also be included in the substrate layer 220. A transfer gate 108 may selectively control the flow of a photocurrent from a photodiode 106 of a pixel sensor 100 to a floating diffusion node 110 of the pixel sensor 100 by selectively controlling a leakage path (e.g., a buried channel) between the photodiode 106 and the floating diffusion node 110 in the substrate layer 220. When a gate voltage is applied to the transfer gate 108, the leakage path may be formed in the substrate layer 220, thereby enabling a photocurrent to flow from the photodiode 106 to the floating diffusion node 110. When the gate voltage is removed, the leakage path is closed, thereby preventing the photocurrent from floating from the photodiode 106 to the floating diffusion node 110.

The semiconductor die 202 may include an interconnect layer 230 vertically adjacent to the device layer 218. The interconnect layer 230 may include a dielectric region 232 that includes one or more dielectric layers. The dielectric layer may include backend dielectric layers (e.g., interlayer dielectric (ILD) layers, intermetal dielectric (IMD) layers) and etch stop layers (ESLs) that are arranged in a direction that is approximately orthogonal to the substrate layer 220. The dielectric region 232 may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 230 may further include a plurality of conductive structures 234 (e.g., electrically conductive structures) in the dielectric region 232. The conductive structures 234 are electrically coupled and/or physically coupled to the transfer gates 108, the floating diffusion nodes 110, and/or other structures in the device layer 218. Moreover, the conductive structures 234 may be electrically interconnected together in the interconnect layer 230. The conductive structures 234 correspond to circuit routing that enables signals and/or power to be provided to and/or from components of the pixel sensors 100 in the device layer 218. The conductive structures 234 may include a combination of conductive structures that extend primarily horizontally in the interconnect layer 230 (e.g., trenches, conductive lines) and that are interconnected by interconnect structures (e.g., vias) that extend primarily vertically in the interconnect layer 230. The conductive structures 234 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 230 may be arranged in a vertical manner to facilitate electrical signals and/or power to be routed between the device layer 218 and the semiconductor die 204, between integrated circuit devices in the device layer 218 through the interconnect layer 230, and/or between the integrated circuit devices in the device layer 218 and integrated circuit devices in the semiconductor dies 204 and/or 206. The conductive structures 234 may be arranged in alternating layers of metallization layers (referred to as “M”-layers) and via layers (referred to as “V”-layers). Each metallization layer may include one or more conductive structures laterally arranged in the interconnect layer 230, and each via layer may include one or more interconnect structures that interconnect the metallization layers in the interconnect layer 230. As an example, a metal-0 (M0) layer may be located at the bottom of the interconnect layer 230 and may be coupled to the integrated circuit devices (e.g., the transfer gates 108, the floating diffusion nodes 110) in the device layer 218, a via-0 (V0) layer may be located above and coupled to the M0 layer in the interconnect layer 230, a metal-1 (M1) layer may be located above and coupled to the V0 layer in the interconnect layer 230, a via-1 (V1) layer may be located above and coupled to the M1 layer in the interconnect layer 230, a metal-2 (M2) layer may be located above and electrically coupled to the V1 layer in the interconnect layer 230, and so on. In some implementations, the interconnect layer 230 includes nine (9) stacked metallization layers (e.g., M0-M8). In other implementations, the contact layer (referred to as “CO”-layer) may be located at the bottom of the interconnect layer 230 and may be directly coupled to the integrated circuit devices (e.g., with the transfer gates 108, with the floating diffusion nodes 110) in the device layer 218, a metal-1 (M1) layer may be located above and coupled to the CO layer in the interconnect layer 230, and so on. In some implementations, the interconnect layer 230 includes another quantity of stacked metallization layers.

At the bonding interface 208a between the semiconductor dies 202 and 204, the interconnect layer 230 may include a plurality of bonding pads 236. The bonding pads 236 may be electrically coupled to the conductive structures 234 in the interconnect layer 230 by bonding vias 238 and/or other types of conductive structures. The bonding pads 236 and the bonding vias 238 may each include tungsten (W), cobalt (Co), ruthenium (Ru), titanium (Ti), aluminum (Al), copper (Cu), gold (Au), and/or a combination thereof, among other examples of electrically conductive metals.

The semiconductor die 204 may be an ASIC die or a system on chip (SoC) die of the semiconductor die package 200. The semiconductor die 204 may include one or more components of the control circuitry regions 104 of the pixel sensors 100 of the semiconductor die package 200. The semiconductor die 204 may include a device layer 240 and an interconnect layer 242 vertically adjacent to the device layer 240. The device layer 240 may include a substrate layer 244 and one or more integrated circuit devices 246 in the substrate layer 244. The substrate layer 244 may include a silicon (Si) substrate, an SOI substrate, and/or another type of substrate. The integrated circuit devices 246 may be each include planar transistors, fin field effect transistors (finFETs), nanostructure (e.g., nanosheet transistors, gate all around (GAA) transistors), and/or other types of integrated circuit devices. Components of the control circuitry regions 104 of the pixel sensors 100 may also be included in the substrate layer 244, such as the reset gates 112, the source-follower gates 116 (not shown), and/or the row-select gates 118 (not shown), among other examples.

The interconnect layer 242 may be located vertically adjacent to the first side (e.g., the frontside) of the substrate layer 244. The interconnect layer 242 may include a similar combination and/or arrangement of structures and/or layers as the interconnect layer 230 of the semiconductor die 202. For example, the interconnect layer 242 may include a dielectric region 248 (similar to the dielectric region 232) and combination of conductive structures 250 (similar to the conductive structures 234) in the dielectric region 248. Moreover, the interconnect layer 242 may include bonding pads 252 that are electrically coupled to one or more of the conductive structures 250 by bonding vias 254. These layers and/or structures may have a reversed vertical arrangement relative to the semiconductor die 202, which enables the semiconductor die 202 and the semiconductor die 204 to be bonded at the bonding interface 208a such that the interconnect layer 230 and the interconnect layer 242 are facing each other and bonded together.

At the bonding interface 208a, the bonding pads 236 of the semiconductor die 202 and bonding pads 252 of the semiconductor die 204 are directly bonded by metal-to-metal bonds. Moreover, the dielectric region 232 of the semiconductor die 202 and the dielectric region 248 of the semiconductor die 204 are directly bonded by dielectric-to-dielectric bonds.

As further shown in FIG. 2, the semiconductor die 204 may include another interconnect layer 256. The interconnect layer 256 may be located on a second side (e.g., a backside) of the substrate layer 244 such that the interconnect layers 242 and 256 are located on vertically opposing sides of the substrate layer 244 of the semiconductor die 204. The interconnect layer 256 may be configured to route signals and/or power between the semiconductor dies 204 and 206. The interconnect layer 256 may include a similar combination and/or arrangement of structures and/or layers as the interconnect layer 242 of the semiconductor die 204. For example, the interconnect layer 256 may include a dielectric region 258 (similar to the dielectric region 248) and a combination of conductive structures 260 (similar to the conductive structures 250) in the dielectric region 258.

One or more elongated conductive structures 262 may be included in the semiconductor die 204. An elongated conductive structure 262 may extend between the interconnect layers 242 and 256 through the substrate layer 244 of the device layer 240. An elongated conductive structure 262 may include a TSV, a metal pillar, a metal column, and/or another type of vertically elongated conductive structure that physically connects and electrically connects with a conductive structure 250 (e.g., a metal pad) in the interconnect layer 242 at a first end, and that physically connects and electrically connects with a conductive structure 260 (e.g., a metal pad) in the interconnect layer 256. An elongated conductive structure 262 may be referred to as a TSV structure in that the elongated conductive structure 262 extends fully through the substrate layer 244 (e.g., a semiconductor substrate such as a silicon substrate) of the device layer 240, as opposed to extending fully through a dielectric layer or an insulator layer. An elongated conductive structure 262 may further extend through a shallow trench isolation (STI) region 264 that is included in the substrate layer 244 of the device layer 240. An elongated conductive structure 262 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. The STI region 264 may include one or more dielectric materials such as a silicon oxide material (SiOₓ such as SiO₂), a silicon nitride material (SiₓN_{y} such Si₃N₄), and/or another suitable dielectric material.

One or more liners 266 may be included between the sidewalls of the elongated conductive structure 262 and the substrate layer 244. The one or more liners 266 may include adhesion liners, barrier liners, diffusion liners, and/or another type of liners. In some implementations, a liner 266 includes a high-k dielectric liner that includes a high-k dielectric material having a dielectric constant that is greater than approximately 3.9. Examples of such materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, a liner 266 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 2A, a doped well region 268 is included in the substrate layer 244 of the semiconductor die 204. The doped well region 268 may be laterally between a sidewall of the elongated conductive structure 262 and the reset gate 112. In some implementations, a source/drain region of the reset gate 112 is included in the doped well region 268. In some implementations, the doped well region 268 is included laterally around the elongated conductive structure 262. In some implementations, the doped well region 268 may fully extend between the frontside and the backside of the substrate layer 244. In some implementations, the doped well region 268 may extend into the substrate layer 244 from the frontside of the substrate layer 244 to a depth such that the source/drain region of the reset gate 112 is fully within the doped well region 268.

The doped well region 268 may electrically connect the capacitor 120 and the capacitor 122 in series, thereby lowering the overall capacitance in the control circuitry regions 104 of the pixel sensors 100. The electrodes of the capacitor 120 may correspond to the elongated conductive structure 262 (first electrode) and the doped well region 268 (second electrode), and the insulator of the capacitor 120 may correspond to the liner 266 on the sidewall of the elongated conductive structure 262 between the elongated conductive structure 262 and the doped well region 268. The electrodes of the capacitor 122 may correspond to the elongated conductive structure 262 (first electrode) and a combination of the doped well region 268 and the source/drain region of the reset gate 112 in the doped well region 268 (second electrode), and the insulator of the capacitor 120 may correspond to the liner 266 on the sidewall of the elongated conductive structure 262 between the elongated conductive structure 262 and the doped well region 268. Thus, the doped well region 268 extends the capacitance to the source/drain region of the reset gate 112, thereby electrically connecting the capacitors 120 and 122 in series between the elongated conductive structure 262 and electrical ground (the substrate layer 244, which is electrically grounded).

The doped well region 268 may include a region of the substrate layer 244 that is doped with one or more types of dopants. Thus, the doped well region 268 includes a region of semiconductor material (e.g., silicon (Si), silicon germanium (SiGe), germanium (Ge)) that is doped with one or more types of dopants. As an example, the doped well region 268 may be doped with one or more n-type dopants such as arsenic (As) and/or phosphorous (P), among other examples. As another example, the doped well region 268 may be doped with one or more p-type dopants such as boron (B) and/or gallium (Ga), among other examples. The dopant type of the doped well region 268 may be different from the dopant type of the substrate layer 244. For example, the doped well region 268 may be doped with n-type dopants and the substrate layer 244 may be doped with p-type dopants. As another example, the doped well region 268 may be doped with n-type dopants and the substrate layer 244 may be undoped.

As further shown in FIG. 2A, the interconnect layer 256 may further include bonding pads 270 and bonding vias 272. The bonding pads 270 enable the semiconductor die 204 to be bonded to the semiconductor die 206 at the bonding interface 208b, and the bonding vias 272 electrically connect one or more of the bonding pads 270 to the conductive structures 260 in the interconnect layer 256.

The semiconductor die 206 may be an image sensor processing (ISP) die of the semiconductor die package 200. The semiconductor die 206 may include the processing circuitry associated with the pixel sensors 100 in the pixel sensor array 210. The processing circuitry may be configured to perform image processing operations for generating images and/or video based on the photocurrents generated by the pixel sensors 100 in the pixel sensor array 210. Additionally and/or alternatively, processing circuitry of the semiconductor die 206 may be configured to perform functions such as compression, storage, file management, and/or other functions associated with the images and/or video.

The semiconductor die 206 may include a device layer 274 and an interconnect layer 276 vertically adjacent to the device layer 274. The device layer 274 may include a substrate layer 278 and one or more integrated circuit devices 280 in the substrate layer 278. The substrate layer 278 may include a silicon (Si) substrate and/or another type of semiconductor substrate. The integrated circuit devices 280 may correspond to the image processing circuitry of the semiconductor die 206 and may include transistors, capacitors, resistors, and/or other integrated circuit devices.

The interconnect layer 276 may be located vertically adjacent to the frontside of the substrate layer 278. The interconnect layer 276 may include a similar combination and/or arrangement of structures and/or layers as the interconnect layer 256 of the semiconductor die 204. For example, the interconnect layer 276 may include a dielectric region 282 (similar to the dielectric region 258) and combination of conductive structures 284 (similar to the conductive structures 260) in the dielectric region 282. Moreover, the interconnect layer 276 may include bonding pads 286 that are electrically coupled to one or more of the conductive structures 284. These layers and/or structures may have a reversed vertical arrangement relative to the interconnect layer 256, which enables the semiconductor die 204 and the semiconductor die 206 to be bonded at the bonding interface 208b such that the interconnect layer 256 and the interconnect layer 276 are facing each other and bonded together.

At the bonding interface 208b, the bonding pads 270 of the semiconductor die 204 and bonding pads 286 of the semiconductor die 206 are directly bonded by metal-to-metal bonds. Moreover, the dielectric region 258 of the semiconductor die 204 and the dielectric region 282 of the semiconductor die 206 are directly bonded by dielectric-to-dielectric bonds.

As shown in FIG. 2B, the doped well region 268 may laterally surround the elongated conductive structure in the top view. The reset gate 112 may include source/drain regions 228a and 228b on opposing sides of a gate structure 290 of the reset gate 112. “Source/drain region” may refer to a source or a drain, individually or collectively dependent upon the context. The source/drain region 228a may be located within the doped well region 268 such that the elongated conductive structure 262, the liner 266, the doped well region 268, and the source/drain region 288a of the reset gate 112 form the series capacitance of the capacitors 120 and 122.

The source/drain region 288a may include a doped region of the substrate layer 244. The source/drain region 288a may be doped with a same dopant type as the doped well region 268. For example, the doped well region 268 and the source/drain region 288a may each be doped with one or more n-type dopants. As another example, the doped well region 268 and the source/drain region 288a may each be doped with one or more p-type dopants. The dopant concentration in the doped well region 268 may be less than the dopant concentration in the source/drain region 288a to minimize current leakage from the reset gate 112. For example, the dopant concentration in the source/drain region 288a may be included in a range of approximately 1×10¹⁸ dopant atoms per cubic centimeter to approximately 1×10²² dopant atoms per cubic centimeter, and the dopant concentration in the doped well region 268 may be approximately 1.1 times to approximately 3 times less than the dopant concentration in the source/drain region 288a to achieve sufficiently low current leakage from the reset gate 112. However, other values and other ranges for the dopant concentrations of the doped well region 268 and the source/drain region 288a of the reset gate 112 are within the scope of the present disclosure.

As further shown in FIG. 2B, the source/drain region 288a of the reset gate 112 may be connected to a gate structure 292 of a source-follower gate 116. The gate structure 292 of the source-follower gate 116 may also be connected to a floating diffusion node 110 of a pixel sensor 100 through the conductive structures 250, the bonding vias 254, the bonding pads 252, the bonding pads 236, the bonding vias 238, and the conductive structures 234. The source-follower gate 116 may include source/drain regions 294a and 294b. The source/drain region 294b of the source-follower gate 116 may be connected to a row-select gate 118. The row-select gate 118 may include a gate structure 296 and source/drain regions 298a and 298b. The source/drain region 298a and the source/drain region 294b may be implemented by the same doped region in the substrate layer 244. The source/drain region 298b may be connected to the elongated conductive structure 262 through one or more conductive structures 250.

As indicated above, FIGS. 2A and 2B are provided as an example. Other examples may differ from what is described with regard to FIGS. 2A and 2B.

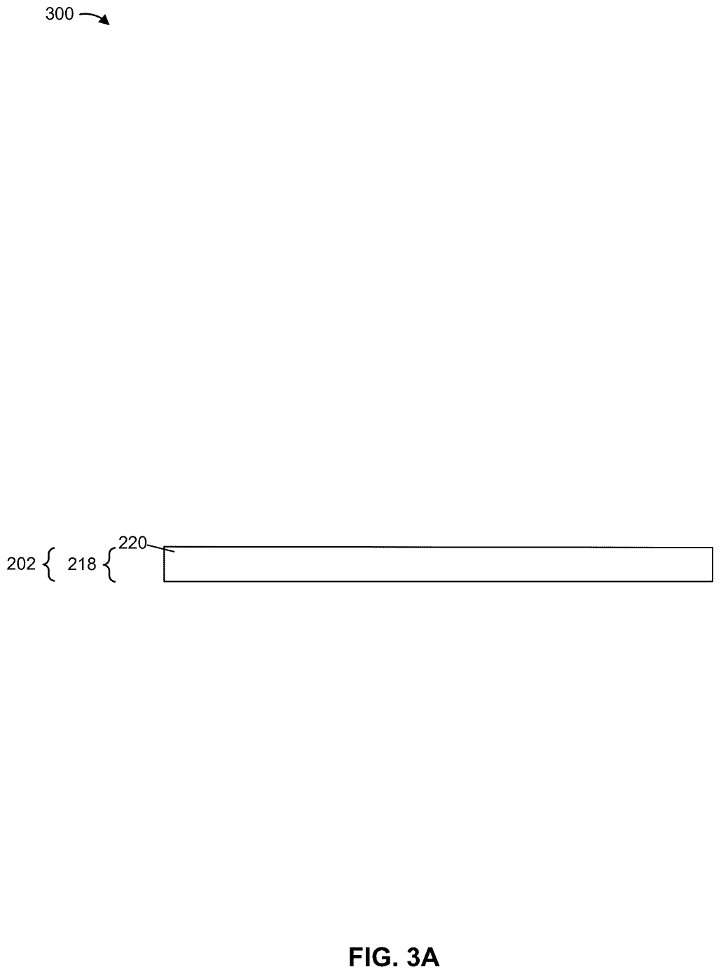

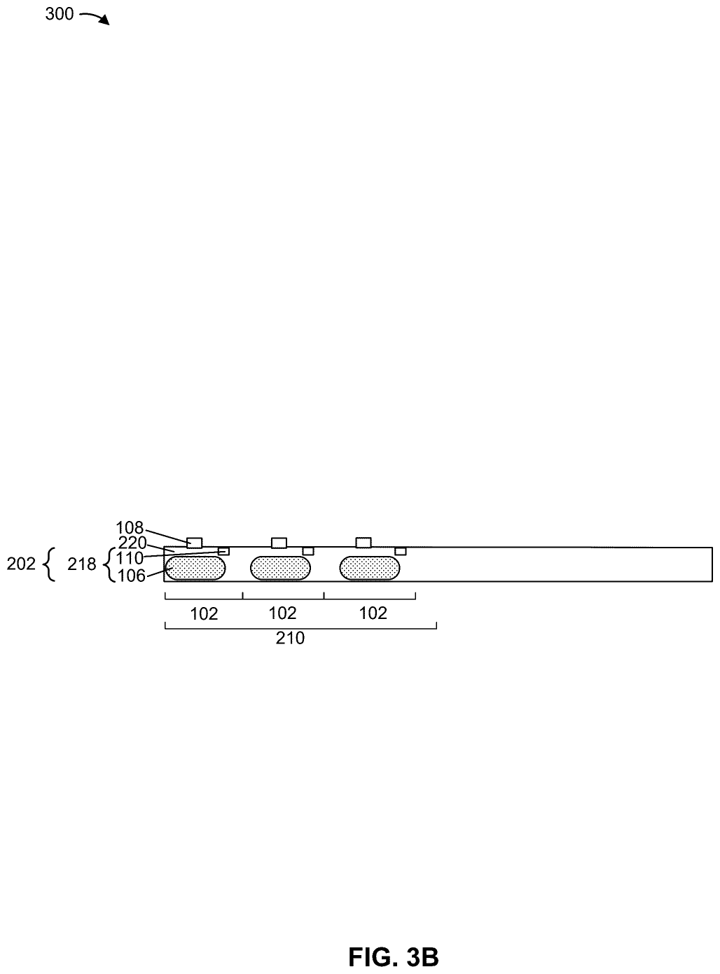

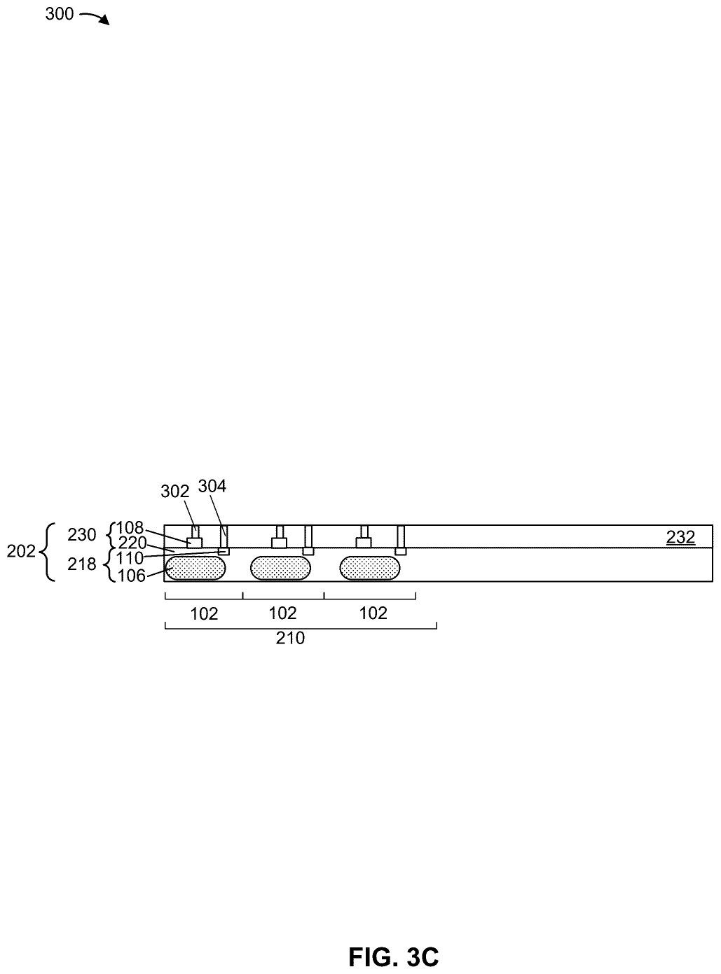

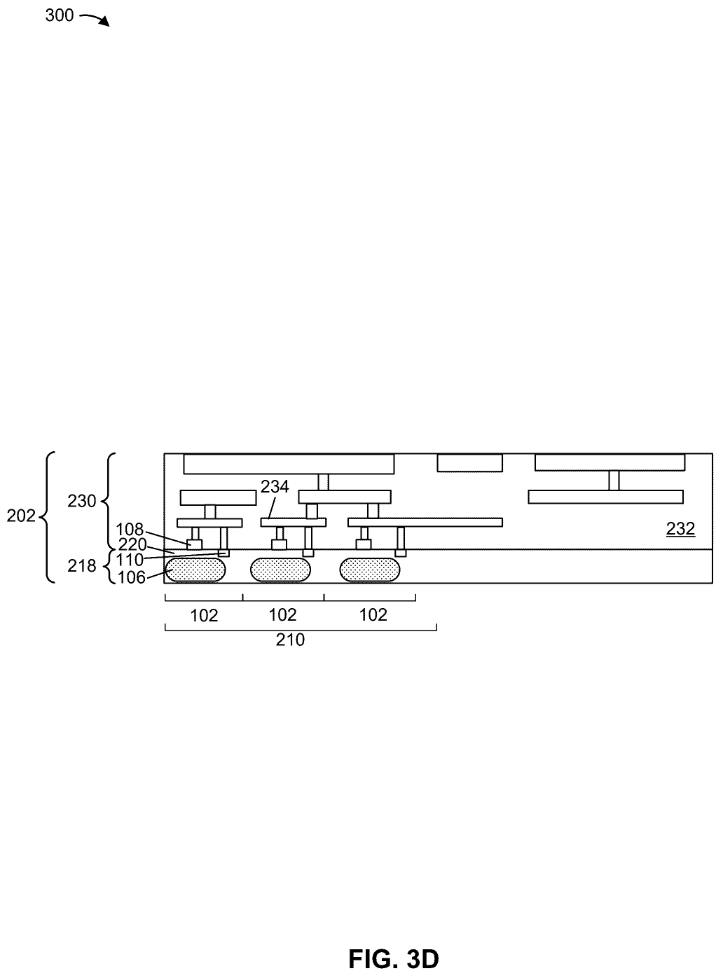

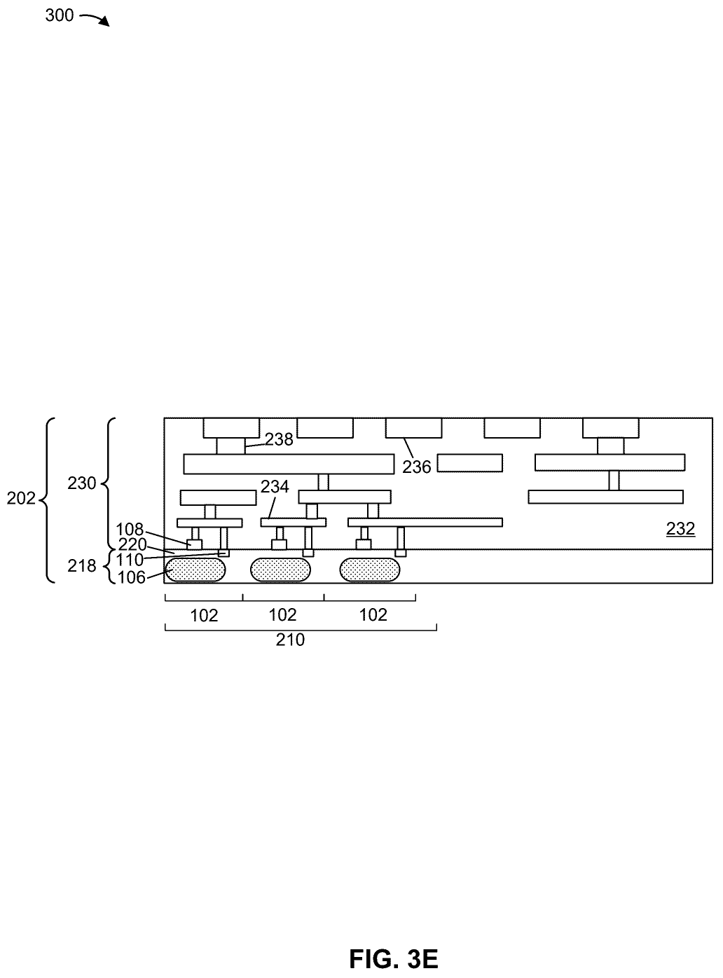

FIGS. 3A-3E are diagrams of an example implementation 300 of forming the semiconductor die 202 (or a portion thereof) described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 3A, the substrate layer 220 of the device layer 218 of the semiconductor die 202 is provided. The substrate layer 220 may be provided in the form of a semiconductor wafer such as a silicon (Si) wafer may be provided as an SOI wafer, and/or another type of semiconductor work piece.

As shown in FIG. 3B, photodiodes 106 of the sensing region 102 of the pixel sensors 100 of the pixel sensor array 210 may be formed in the substrate layer 220 of the semiconductor die 202. The photodiodes 106 may be formed from the frontside of the substrate layer 220. In some implementations, an ion implantation tool may be used to implant ions into the substrate layer 220 to form a P-N junction between a p-doped region of the substrate layer 220 and an n-doped region of the substrate layer 220, or to form a P-I-N junction between p-doped region of the substrate layer 220, an n-doped region of the substrate layer 220, and an intrinsic (e.g., undoped) semiconductor region for a photodiode 106.

As further shown in FIG. 3B, additional regions of the substrate layer 220 may be doped to form the floating diffusion nodes 110. Transfer gates 108 of the pixel sensors 100 may be formed over and/or on the frontside surface of the substrate layer 220. Forming a transfer gates 108 may include deposing a gate dielectric on the front side surface of the substrate layer 220, depositing a gate electrode on the gate dielectric layer, and/or forming sidewall spacers on sidewalls of the gate electrode, among other examples.

As in FIG. 3C, a portion of the dielectric region 232 of the interconnect layer 230 of the semiconductor die 202 may be formed over the frontside of the substrate layer 220. A deposition tool may be used to deposit the portion of the dielectric region 232 using a physical vapor deposition (PVD) technique, an atomic layer deposition (ALD) technique, a chemical vapor deposition (CVD) technique, an oxidation technique, and/or another suitable deposition technique. The portion of the dielectric region 232 may be deposited in one or more deposition operations. In some implementations, a planarization tool may be used to perform a planarization operation (e.g., a chemical mechanical planarization (CMP) operation) to planarize the portion of the dielectric region 232 after the portion of the dielectric region 232 is deposited.

Gate contacts 302 and source/drain contacts 304 may be formed in the dielectric region 232. For example, the gate contacts 302 may be formed on the transfer gates 108 of the pixel sensors 100, and the source/drain contacts 304 may be formed on the floating diffusion nodes 110 of the pixel sensors 100. To form the gate contacts 302 and the source/drain contacts 304, recesses may be formed in the dielectric region 232, and the gate contacts 302 and the source/drain contacts 304 may be formed in the recesses in the dielectric region 232. A deposition tool may be used to deposit the gate contacts 302 and the source/drain contacts 304 using a CVD technique, a PVD technique, an ALD technique, an electroplating technique, and/or another suitable deposition technique. The gate contacts 302 and the source/drain contacts 304 may be deposited in one or more deposition operations. In some implementations, a seed layer is first deposited, and the gate contacts 302 and the source/drain contacts 304 are deposited on the seed layer. In some implementations, one or more liners (e.g., adhesion liners, barrier liners, diffusion liners) are deposited, and then the gate contacts 302 and the source/drain contacts 304 are deposited on the liners. In some implementations, a planarization tool is used to perform a planarization operation (e.g., a CMP operation) to planarize the gate contacts 302 and the source/drain contacts 304 after the gate contacts 302 and the source/drain contacts 304 are deposited.

As shown in FIG. 3D, additional portions of the interconnect layer 230 of the semiconductor die 202 may be formed above the frontside of the substrate layer 220. One or more semiconductor processing tools may be used to form the interconnect layer 230 by forming one or more dielectric layers of the dielectric region 232 and forming a plurality of conductive structures 234 in the dielectric layer(s) of the dielectric region 232. For example, a deposition tool may be used to deposit a first dielectric layer of the dielectric region 232 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 234 in the recesses (e.g., using a CVD technique, an ALD technique, a PVD technique, an electroplating technique, and/or another type of deposition technique). At least a portion of the first layer of conductive structures 234 may be electrically connected and/or physically connected with the transfer gates 108 and/or with the floating diffusion nodes 110 (e.g., directly connected or connected through contacts 302 and/or 304). Similar processing operations may be performed to form additional layers of the interconnect layer 230 until a sufficient or desired arrangement of conductive structures 234 is achieved.

As shown in FIG. 3E, the bonding vias 238 may be formed on one or more conductive structures 234 in the interconnect layer 230, and bonding pads 236 may be formed above the bonding vias 238. In some implementations, one or more bonding pads 236 are formed on one or more bonding vias 238.

As indicated above, FIGS. 3A-3E are provided as an example. Other examples may differ from what is described with regard to FIGS. 3A-3E.

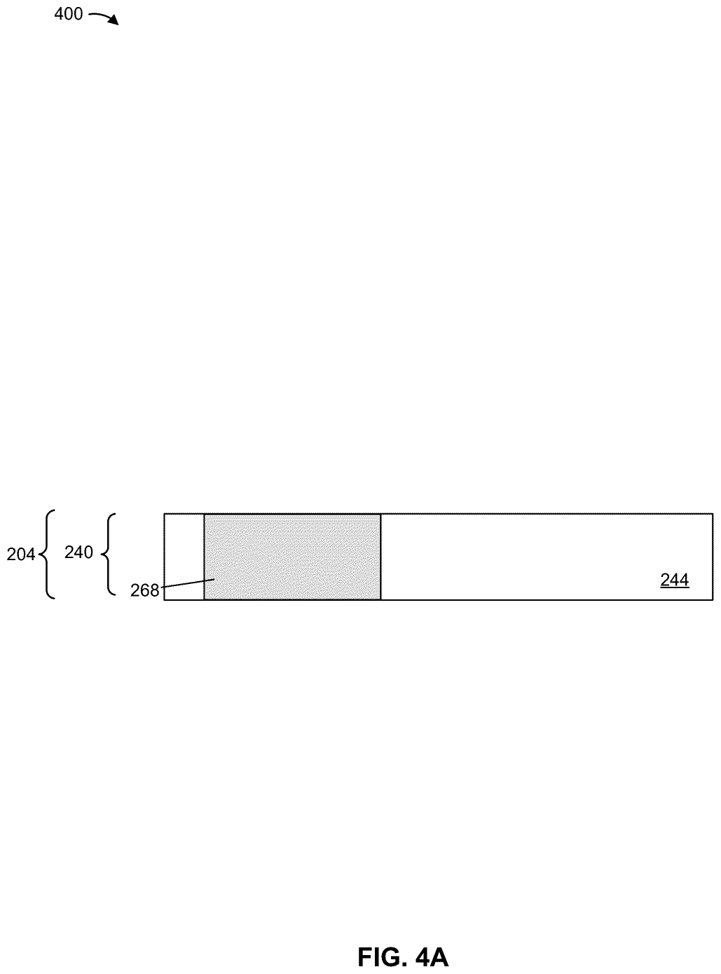

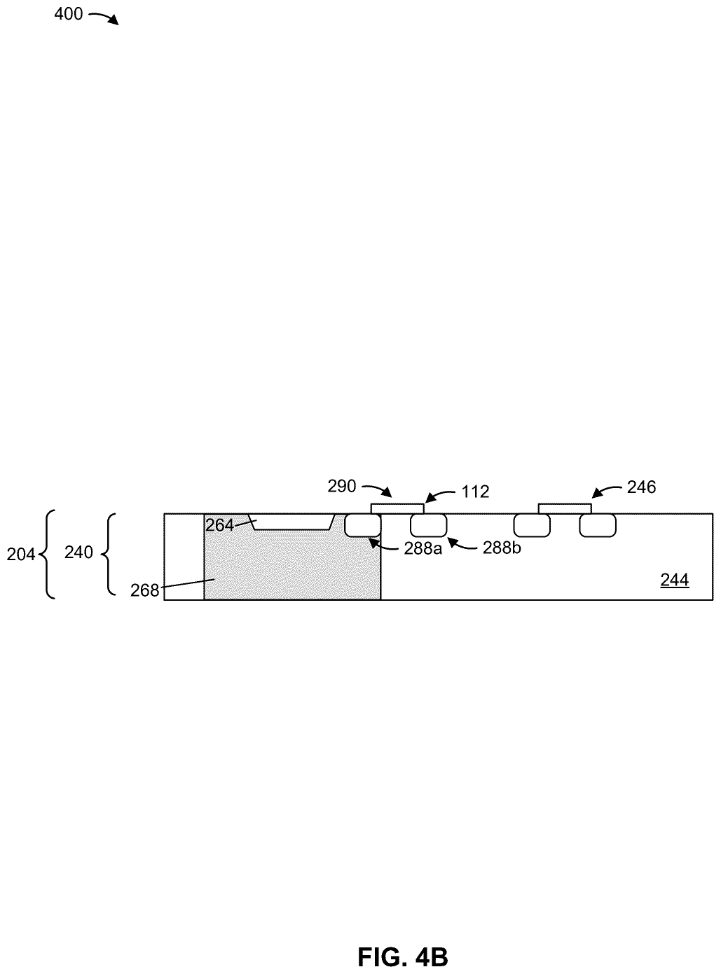

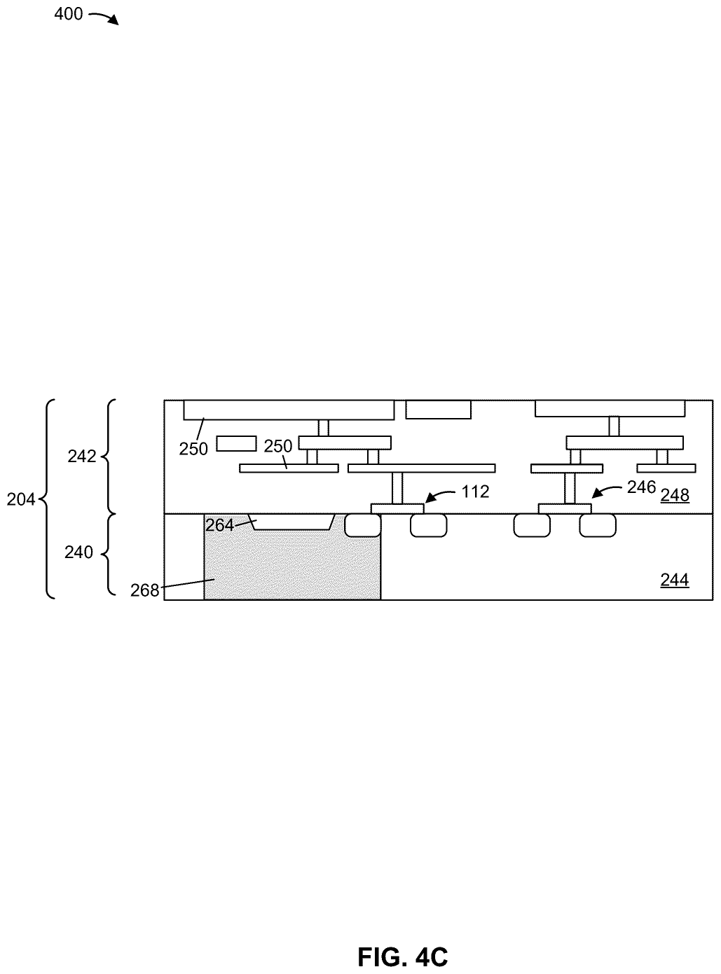

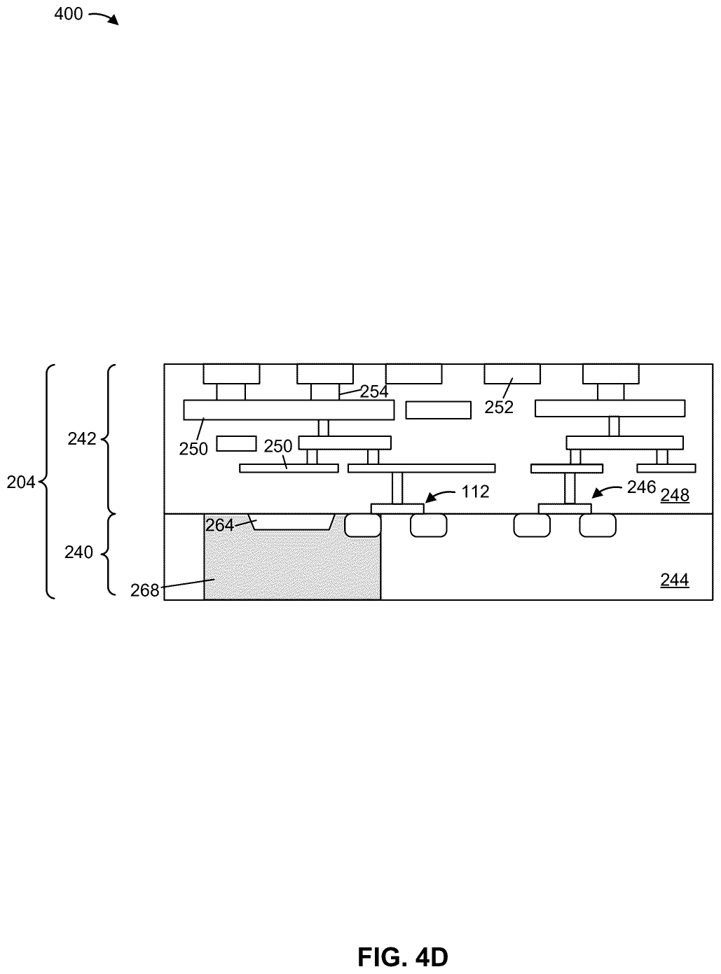

FIGS. 4A-4D are diagrams of an example implementation 400 of forming the semiconductor die 204 (or a portion thereof) described herein. In some implementations, the example implementation 400 includes an example frontside process for the semiconductor die 204. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

Turning to FIG. 4A, one or more of the operations in the example implementation 400 may be performed in connection with the substrate layer 244 of the device layer 240 of the semiconductor die 204. The substrate layer 244 may be provided in the form of a semiconductor wafer (e.g., a silicon wafer), an SOI wafer, or another type of semiconductor substrate.

As further shown in FIG. 4A, a portion of the substrate layer 244 may be doped to form the doped well region 268 in the substrate layer 244. The substrate layer 244 may be doped from the frontside of the substrate layer 244 to form the doped well region 268. For example, an ion implantation tool may be used to implant ions (e.g., n-type ions, p-type ions) into the substrate layer 244 from the frontside of the substrate layer 244 to form the doped well region 268. As another example, a diffusion tool may be used to perform a diffusion operation in which dopants are diffused into the substrate layer 244 from the frontside of the substrate layer 244. In some implementations, the doped well region 268 fully extends from the frontside to the backside of the substrate layer 244. In some implementations, the doped well region 268 extends into a portion from the frontside of the substrate layer 244.

As shown in FIG. 4B, the integrated circuit devices 246 may be formed in and/or on the frontside of the substrate layer 244 of the device layer 240. Moreover, the reset gates 112, the source-follower gates 116 (not shown), and/or the row-select gates 118 (not shown) of the pixel sensors 100 may be formed in and/or on the substrate layer 244.

One or more semiconductor processing tools may be used to form one or more portions of the integrated circuit devices 246. For example, a deposition tool may be used to perform various deposition operations to deposit layers of the integrated circuit devices 246, and/or to deposit photoresist layers for etching the substrate layer 244 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 244 and/or portions of the deposited layers to form the integrated circuit devices 246. As another example, a planarization tool may be used to planarize portions of the integrated circuit devices 246. As another example, an ion implantation tool may be used to implant ions in the substrate layer 244 to dope portions of the substrate layer 244 with one or more types of dopants (e.g., p-type dopants, n-type dopants).

The source/drain regions 288a, 288b, and the gate structure 290 of the reset gate 112 may be formed by performing similar processing operations. The source/drain region 288a of the reset gate 112 may be formed in the doped well region 268 such that the doped well region 268 and the source/drain region 288a are electrically connected. For example, an ion implantation tool may be used to implant ions in a portion of the doped well region 268 to form the source/drain region 288a. The source/drain region 288a may be doped with a greater concentration of dopants than the doped well region 268. In this way, the dopant concentration in the source/drain region 288a may be greater than the dopant concentration in the doped well region 268.

As further shown in FIG. 4B, an STI region 264 may be formed in the frontside of the substrate layer 244 such that the STI region 264 is located in the doped well region 268. The STI region 264 may be formed in a recess in the substrate layer 244. In some implementations, a pattern in a photoresist layer is used to etch the substrate layer 244 to form the recess in the substrate layer 244. In these implementations, a deposition tool may be used to form the photoresist layer on the substrate layer 244. An exposure tool may be used to expose the photoresist layer to a radiation source to pattern the photoresist layer. A developer tool may be used to develop and remove portions of the photoresist layer to expose the pattern. An etch tool may be used to etch the substrate layer 244 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 244 based on a pattern.

A deposition tool may be used to deposit the dielectric material of the STI region 264 in the recess using a CVD technique, an ALD technique, a PVD technique, an oxidation technique, and/or another suitable deposition technique. The dielectric material of the STI region 264 may be deposited in one or more deposition operations. In some implementations, a planarization tool may be used to perform a planarization operation (e.g., a CMP operation) to planarize the STI region 264 after the dielectric material of the STI region 264 is deposited.

As shown in FIG. 4C, the interconnect layer 242 of the semiconductor die 204 may be formed above the frontside of the substrate layer 244 of the semiconductor die 204. One or more semiconductor processing tools may be used to form the interconnect layer 242 by forming one or more dielectric layers of the dielectric region 248 of the interconnect layer 242 and forming a plurality of conductive structures 250 in the dielectric layer(s) of the dielectric region 248. For example, a deposition tool may be used to deposit a first dielectric layer of the dielectric region 248 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 250 in the recesses (e.g., using a CVD technique, an ALD technique, a PVD technique, an electroplating technique, and/or another type of deposition technique). At least a portion of the first layer of conductive structures 250 may be electrically connected and/or physically connected with the integrated circuit devices 246, the reset gates 112, the source-follower gates 116, and/or the row-select gates 118 in the substrate layer 244 (e.g., directly connected or connected through contacts). Similar processing operations may be performed to form additional layers of the interconnect layer 242 until a sufficient or desired arrangement of conductive structures 250 is achieved.

As shown in FIG. 4D, the bonding vias 254 may be formed on one or more conductive structures 250 in the interconnect layer 242, and bonding pads 252 may be formed above and/or on the bonding vias 254.

As indicated above, FIGS. 4A-4D are provided as an example. Other examples may differ from what is described with regard to FIGS. 4A-4D.

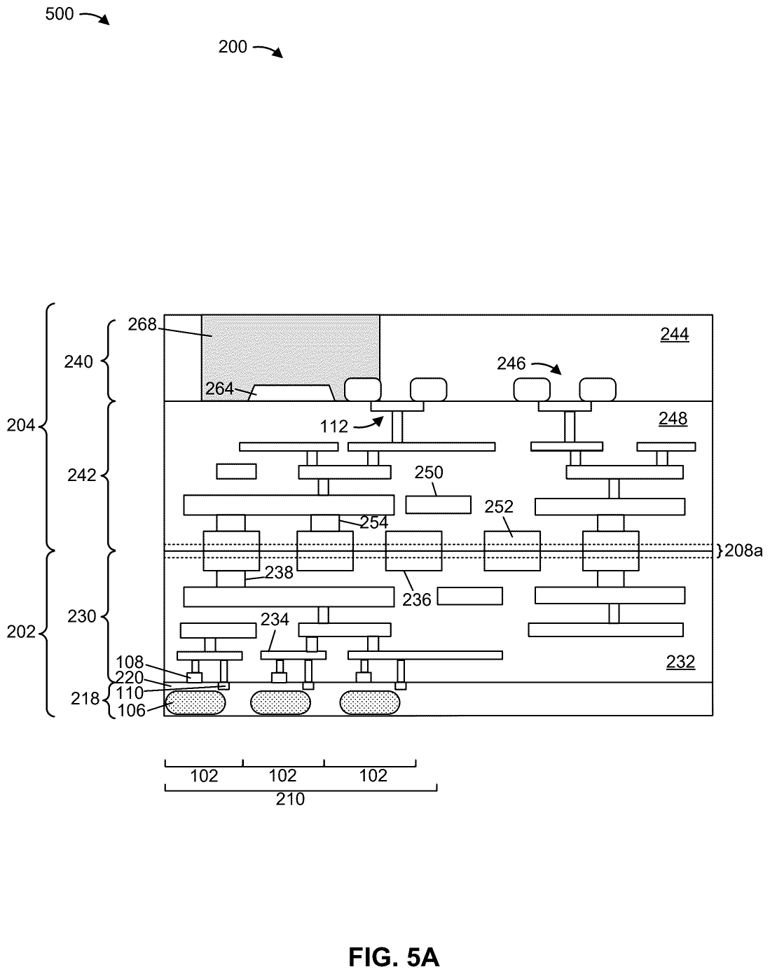

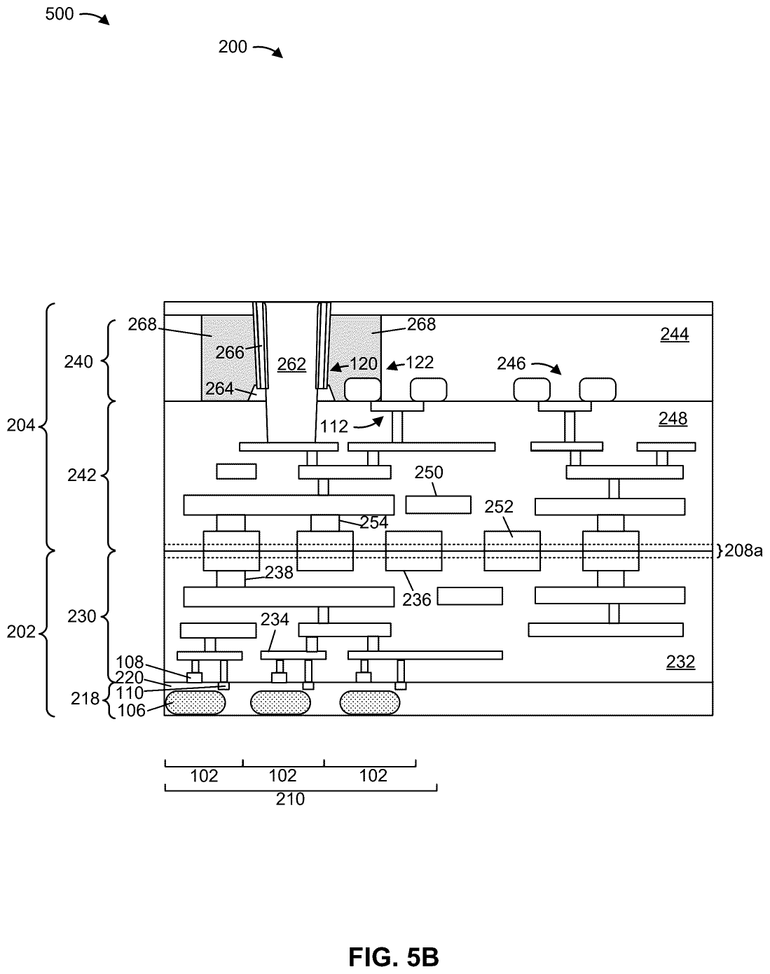

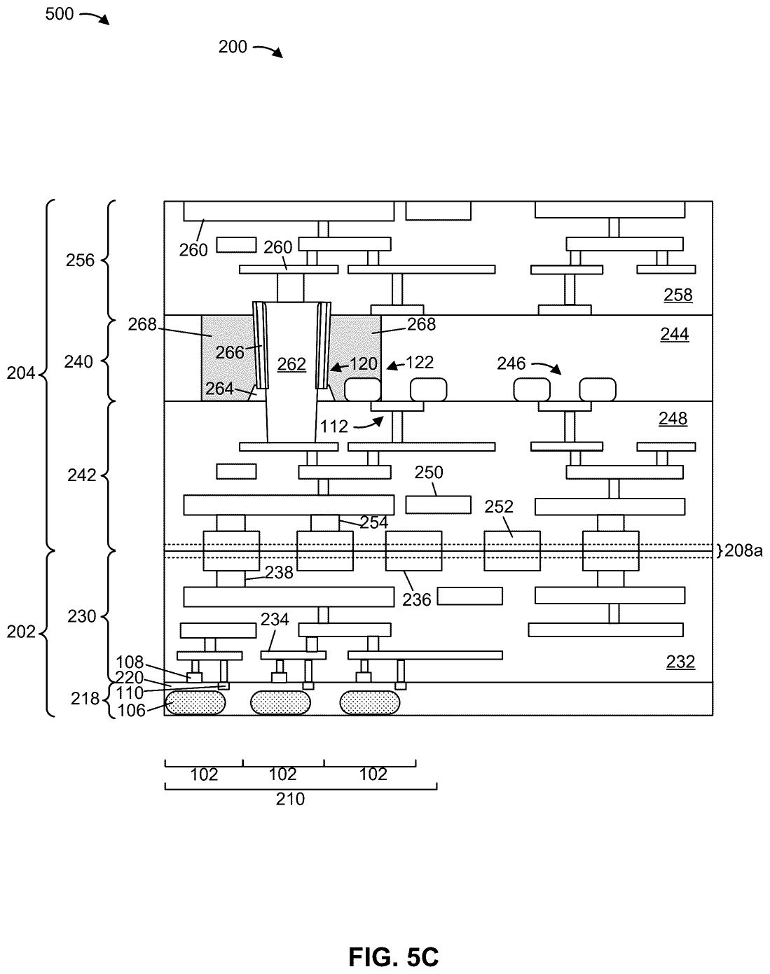

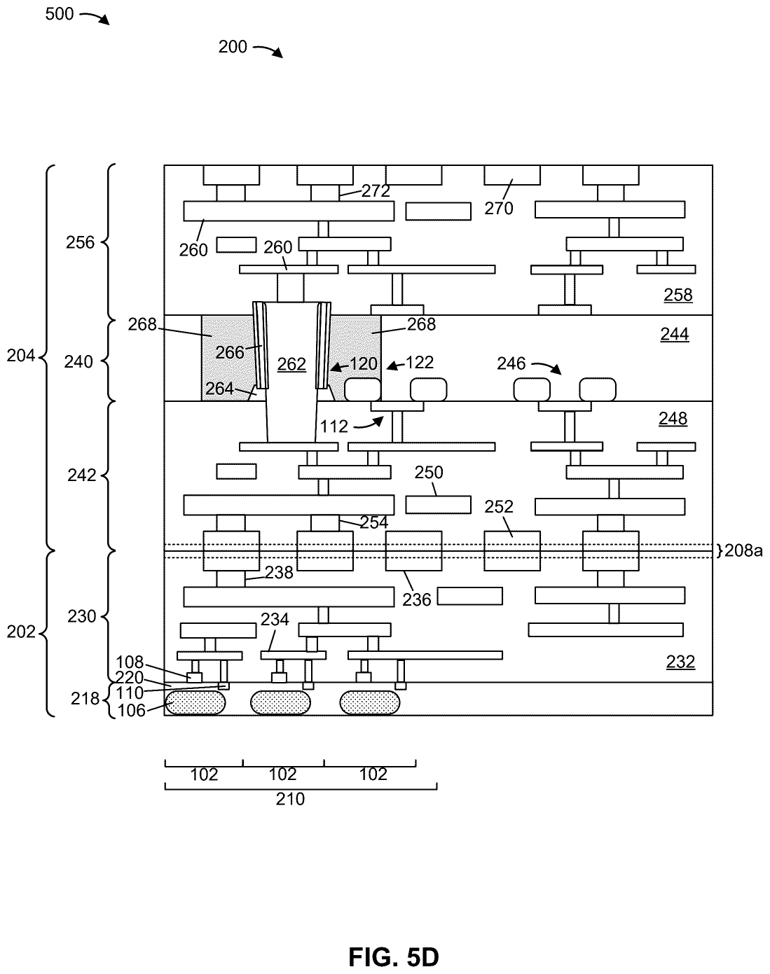

FIGS. 5A-5D are diagrams of an example implementation 500 of forming the semiconductor die package 200 (or a portion thereof) described herein. For example, the example implementation 500 may include an example of bonding the semiconductor dies 202 and 204 of the semiconductor die package 200, and performing backside processing on the semiconductor die 204 after bonding. In some implementations, one or more semiconductor processing tools may be used to perform one or more of the operations described in connection with the example implementation 500, such as a deposition tool, an exposure tool, a developer tool, an etch tool, a planarization tool, a bonding tool, and/or another type of semiconductor processing tool.

As shown in FIG. 5A, a bonding operation is performed to bond the semiconductor die 202 and the semiconductor die 204 at the bonding interface 208a such that the semiconductor die 202 and the semiconductor die 204 are vertically arranged or stacked in the semiconductor die package 200. The semiconductor die 202 and the semiconductor die 204 may be bonded at the bonding interface 208a after the doped well region 268 is formed in the substrate layer 244 during frontside processing of the semiconductor die 204.

The semiconductor die 202 and the semiconductor die 204 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 202 and the semiconductor die 204 at the bonding interface 208a. The bonding operation may include forming a direct bond between the semiconductor die 202 and the semiconductor die 204 through a direct physical connection of the bonding pads 236 of the semiconductor die 202 with the bonding pads 252 of the semiconductor die 204, and through a direct physical connection of the dielectric region 232 of the semiconductor die 202 with the dielectric region 248 of the semiconductor die 204. In this way, the interconnect layer 230 on the frontside of the semiconductor die 202 and the interconnect layer 242 on the frontside of the semiconductor die 204 are facing each other in the semiconductor die package 200.

As shown in FIG. 5B, backside processing may be performed on the backside of the semiconductor die 204 after the semiconductor dies 202 and 204 are bonded at the bonding interface 208a. The backside processing may include forming one or more elongated conductive structures 262 (e.g., one or more TSVs) through the substrate layer 244 of the semiconductor die 204 such that the one or more elongated conductive structures 262 land on one or more conductive structures 250 in the interconnect layer 242 on the frontside of the semiconductor die 204.

An elongated conductive structure 262 may be formed through the doped well region 268 in the substrate layer 244 adjacent to the reset gate 112. In this way, the doped well region 268 may laterally surround the elongated conductive structure 262. Formation of the elongated conductive structure 262 through the doped well region 268 results in formation of a series capacitance connection of capacitors 120 and 122 through the doped well region 268.

To form an elongated conductive structure 262, a recess may be formed through doped well region 268 in the substrate layer 244 from the backside of the substrate layer 244. The recess may extend through the STI region 264 in the substrate layer 244, and into the dielectric region 248 in the interconnect layer 242. A conductive structure 250 in the interconnect layer 242 may be exposed through the recess.

In some implementations, a pattern in a photoresist layer is used to etch the substrate layer 244, the STI region 264, and/or the dielectric region 248 to form the recess. In these implementations, a deposition tool may be used to form the photoresist layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the doped well region 268 in the substrate layer 244, the STI region 264, and/or the dielectric region 248 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

One or more liners 266 (e.g., adhesion liners, barrier liners, diffusion liners) are deposited in the recess, and then the elongated conductive structure 262 is deposited on the liners(s) 266. A deposition tool may be used to deposit the material of the elongated conductive structure 262 in the recess using a CVD technique, a PVD technique, an ALD technique, an electroplating technique, and/or another suitable deposition technique. The elongated conductive structure 262 may be deposited in one or more deposition operations. In some implementations, a seed layer is first deposited, and the elongated conductive structure 262 is deposited on the seed layer. In some implementations, a planarization tool is used to perform a planarization operation (e.g., a CMP operation) to planarize the elongated conductive structure 262 after the elongated conductive structure 262 is deposited.

As shown in FIG. 5C, the interconnect layer 256 of the semiconductor die 204 may be formed above the backside of the substrate layer 244 of the semiconductor die 204. One or more semiconductor processing tools may be used to form the interconnect layer 256 by forming one or more dielectric layers of the dielectric region 258 of the interconnect layer 256 and forming a plurality of conductive structures 260 in the dielectric layer(s) of the dielectric region 258. For example, a deposition tool may be used to deposit a first dielectric layer of the dielectric region 258 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 260 in the recesses (e.g., using a CVD technique, an ALD technique, a PVD technique, an electroplating technique, and/or another type of deposition technique). At least a portion of the first layer of conductive structures 260 may be electrically connected and/or physically connected with the elongated conductive structure 260. Similar processing operations may be performed to form additional layers of the interconnect layer 256 until a sufficient or desired arrangement of conductive structures 260 is achieved.

As shown in FIG. 5D, the bonding vias 272 may be formed on one or more conductive structures 260 in the interconnect layer 256, and bonding pads 270 may be formed above and/or on the bonding vias 272.

As indicated above, FIGS. 5A-5D are provided as an example. Other examples may differ from what is described with regard to FIGS. 5A-5D.

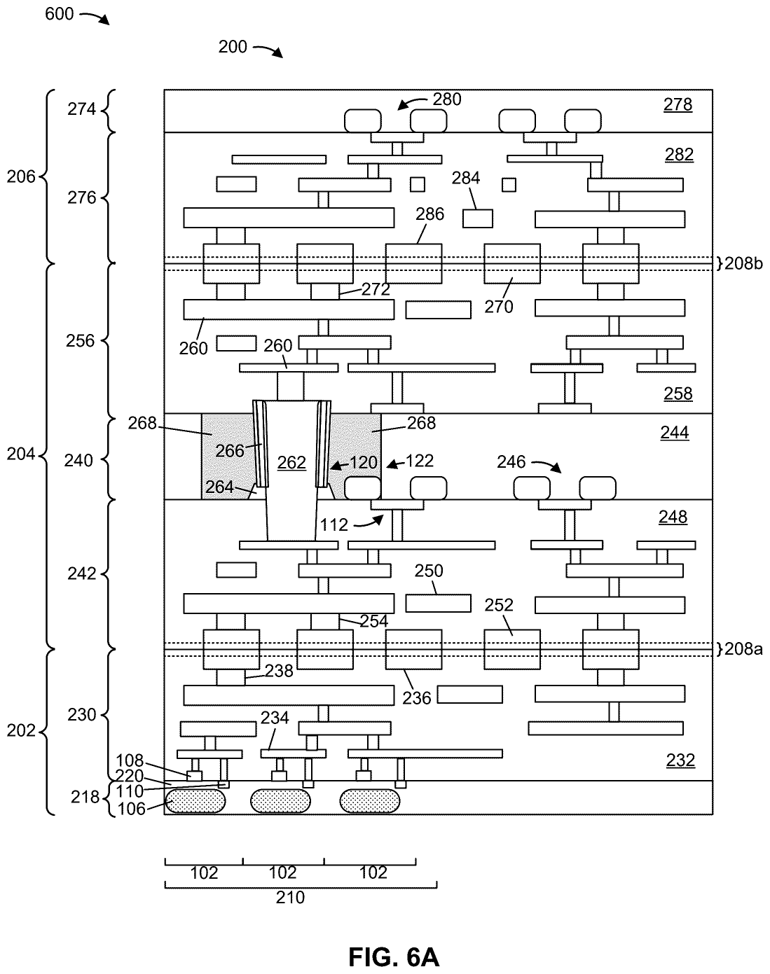

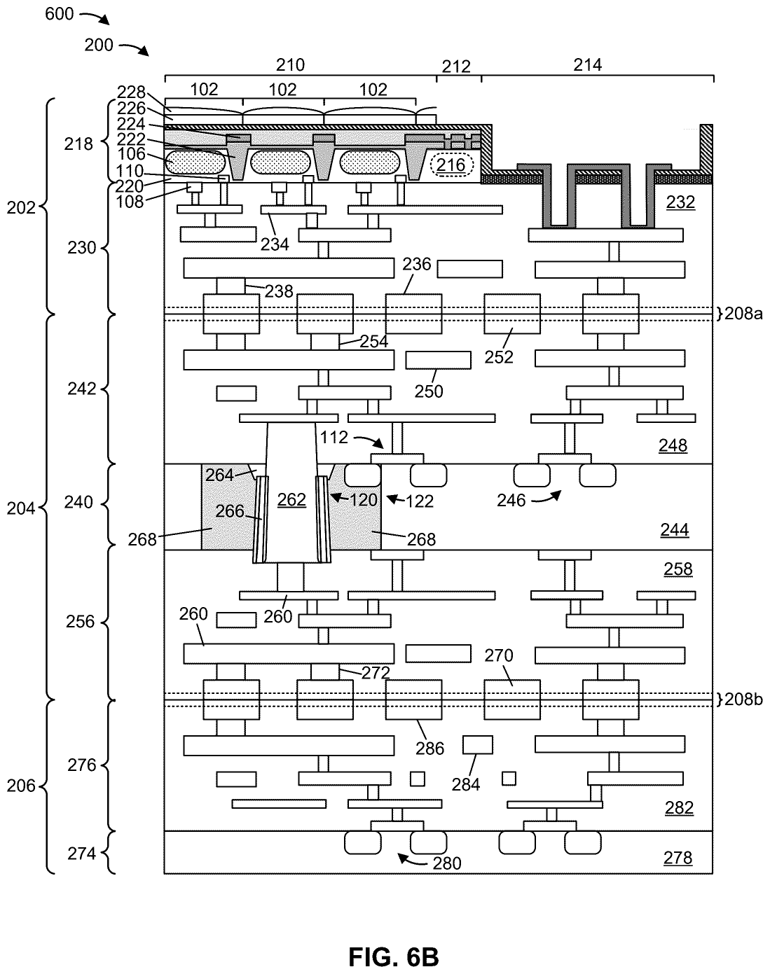

FIGS. 6A and 6B are diagrams of an example implementation 600 of forming the semiconductor die package 200 (or a portion thereof) described herein. For example, the example implementation 600 may include an example of bonding the semiconductor dies 204 and 206 of the semiconductor die package 200, and performing backside processing on the semiconductor die 202 after bonding. In some implementations, one or more semiconductor processing tools may be used to perform one or more of the operations described in connection with the example implementation 600, such as a deposition tool, an exposure tool, a developer tool, an etch tool, a planarization tool, a bonding tool, and/or another type of semiconductor processing tool.

As shown in FIG. 6A, a bonding operation is performed to bond the semiconductor die 204 and the semiconductor die 206 at the bonding interface 208b such that the semiconductor die 204 and the semiconductor die 206 are vertically arranged or stacked in the semiconductor die package 200. The semiconductor die 204 and the semiconductor die 206 may be vertically arranged or stacked in a WoW configuration, a die on wafer configuration, a die on die configuration, and/or another direct bonding configuration. A bonding tool may be used to perform the bonding operation to bond the semiconductor die 204 and the semiconductor die 206 at the bonding interface 208b. The bonding operation may include forming a direct bond between the semiconductor die 204 and the semiconductor die 206 through a direct physical connection of the bonding pads 270 of the semiconductor die 204 with the bonding pads 286 of the semiconductor die 206, and through a direct physical connection of the dielectric region 258 of the semiconductor die 204 with the dielectric region 282 of the semiconductor die 206. In this way, the interconnect layer 256 on the backside of the semiconductor die 204 and the interconnect layer 276 on the frontside of the semiconductor die 206 are facing each other in the semiconductor die package 200.

The semiconductor die 206 may be formed by similar operations and/or using similar techniques as described in connection with FIGS. 4A-4D for the semiconductor die 204.

As shown in FIG. 6B, backside processing may be performed on the backside of the semiconductor die 202 after the semiconductor dies 204 and 206 are bonded at the bonding interface 208b. The backside processing may include additional processing to form the pixel sensor array 210, the BLC region 212, and/or the bonding pad region 214. For example, the DTI structure 222 may be formed in the backside of the substrate layer 220 such that the DTI structure 222 laterally surrounds the photodiodes 106 of the pixel sensors 100. As another example, the metal grid structure 224 may be formed above the backside of the substrate layer 220, the color filter regions 226 may be above the photodiodes 106 on the backside of the substrate layer 220, and the micro-lenses 228 may be formed above the color filter regions 226. As another example, a metal shielding layer may be formed over the region 216 in the BLC region 212. As another example, a bonding pad structure may be formed in the bonding pad region 214.

As indicated above, FIGS. 6A and 6B are provided as an example. Other examples may differ from what is described with regard to FIGS. 6A and 6B.

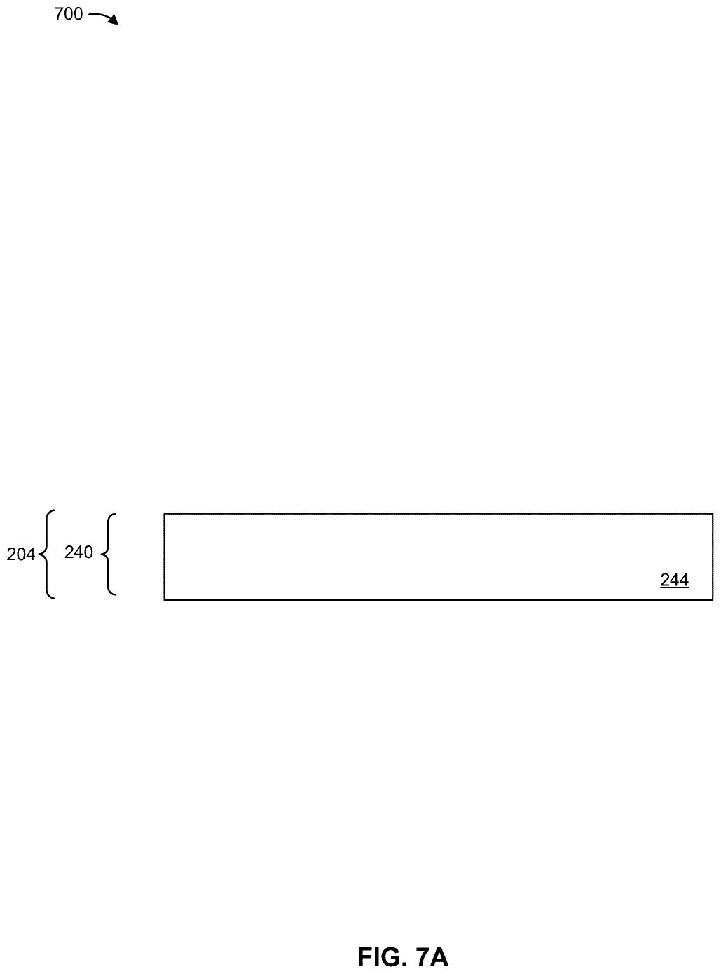

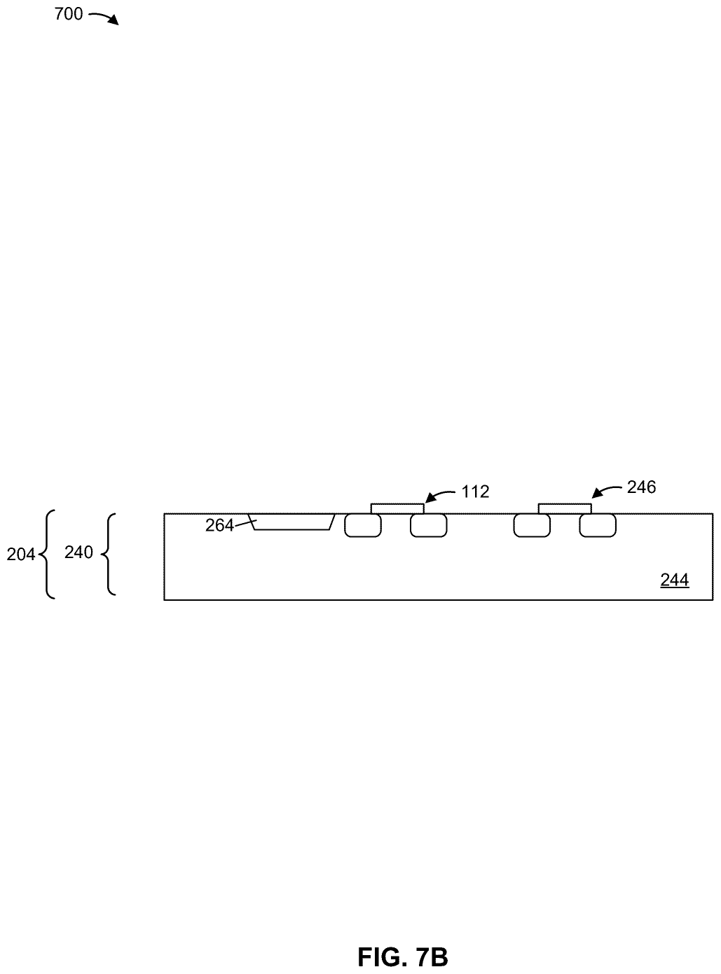

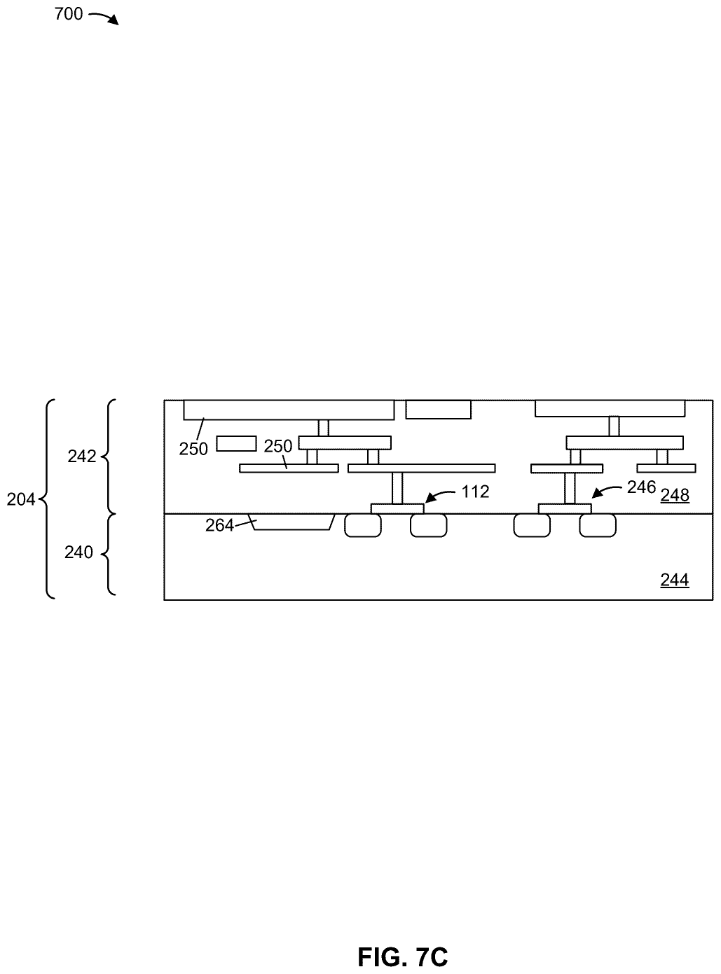

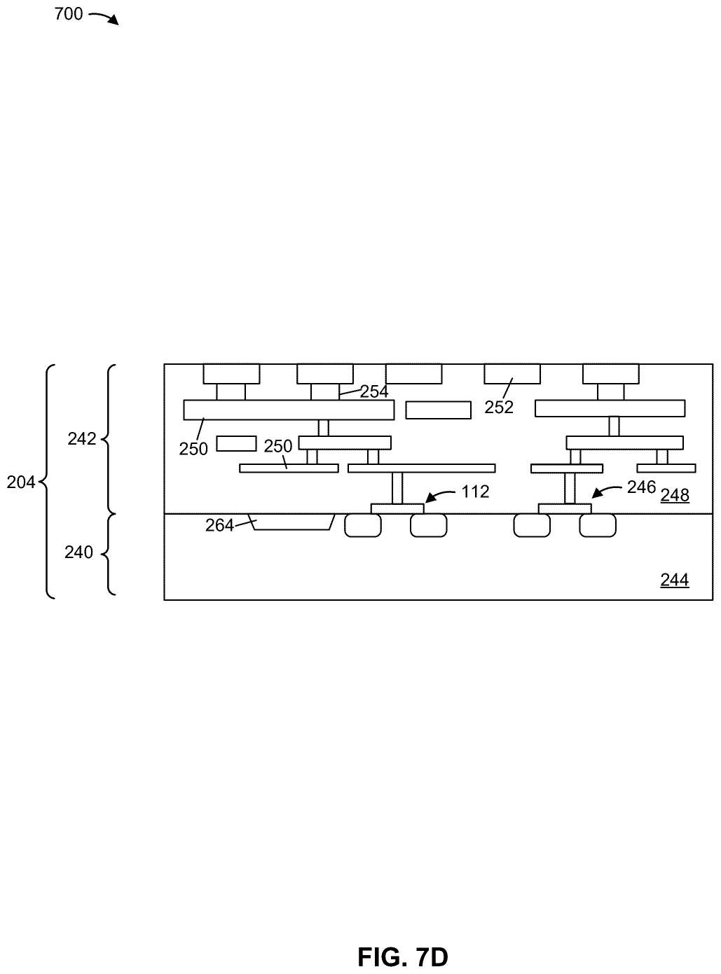

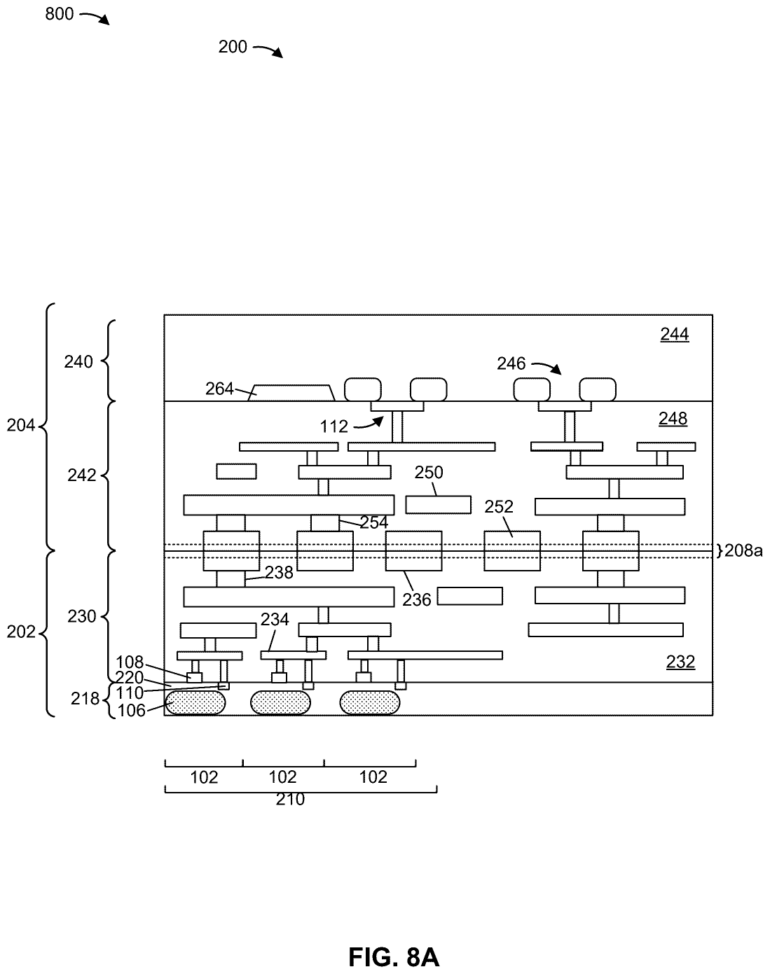

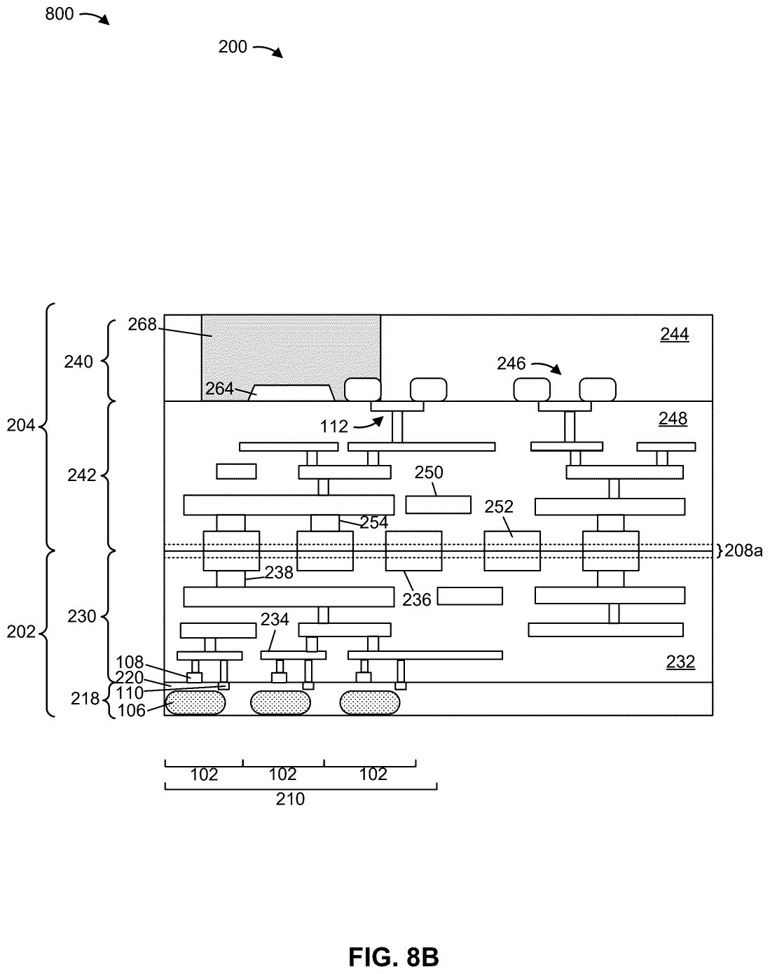

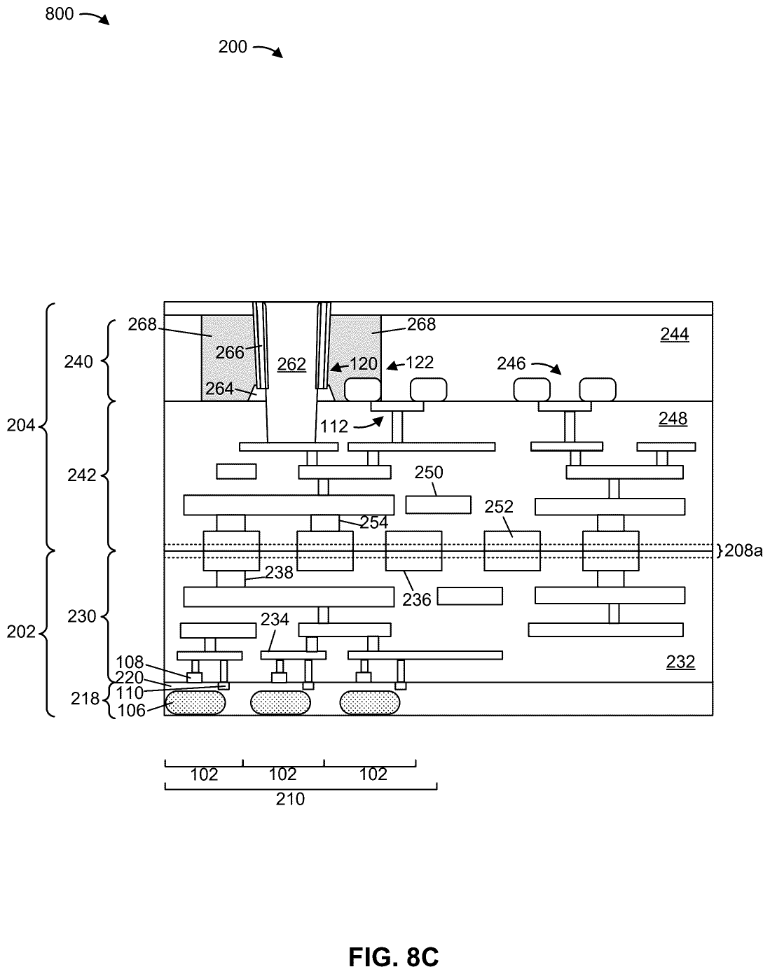

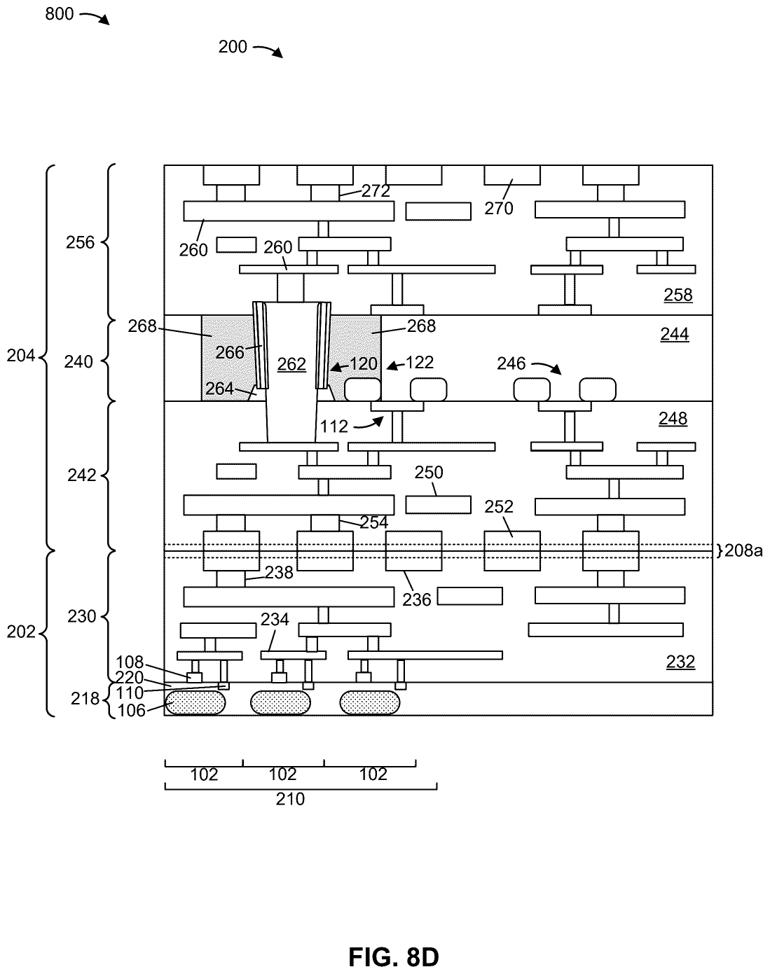

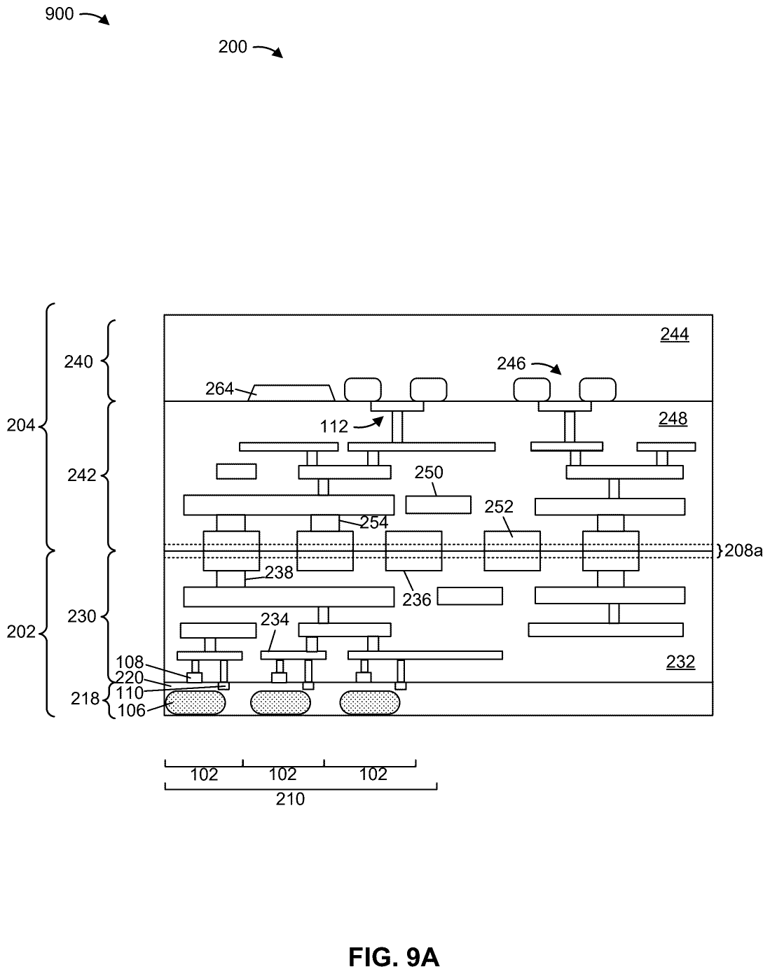

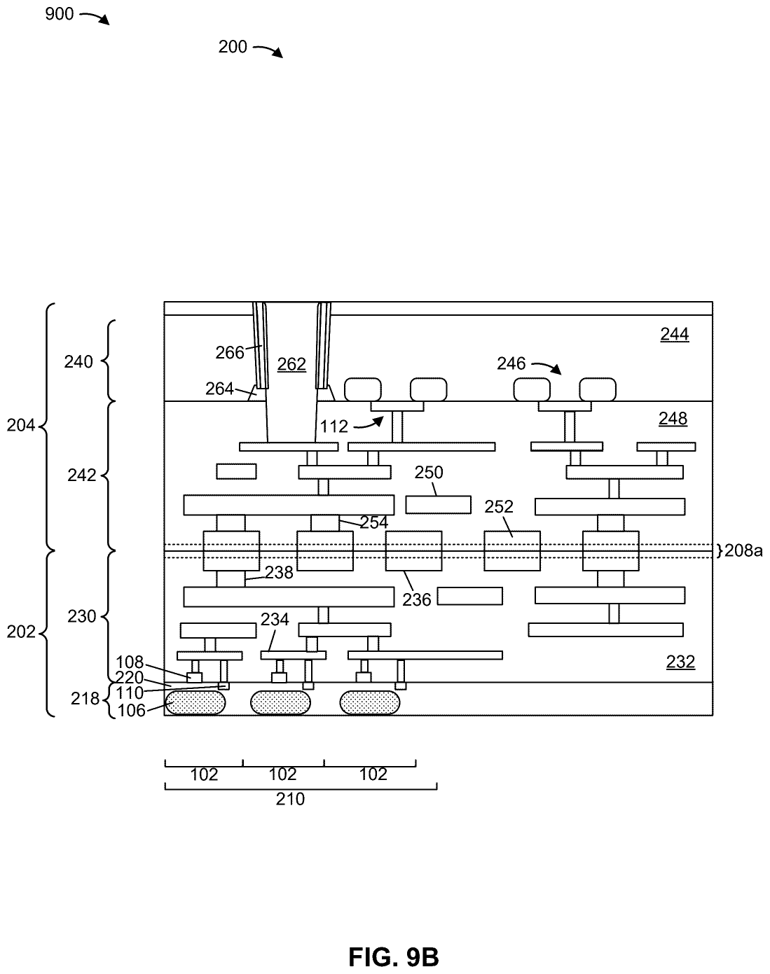

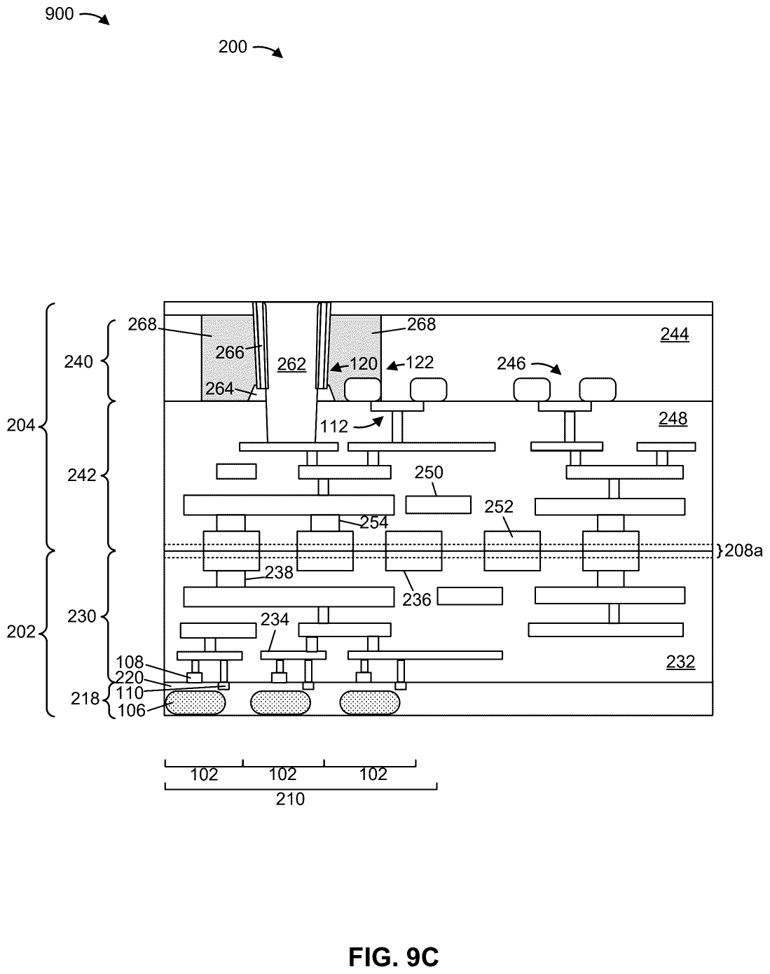

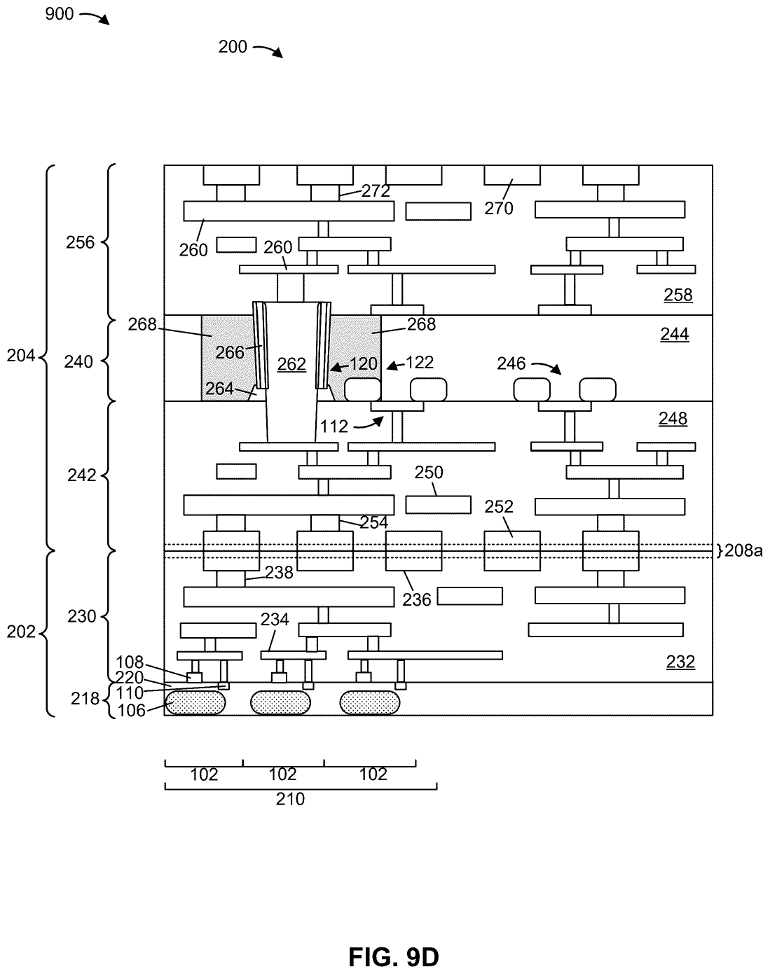

FIGS. 7A-7D are diagrams of an example implementation 700 of forming the semiconductor die 204 (or a portion thereof) described herein. The example implementation 700 includes an alternative example frontside process for the semiconductor die 204. The frontside process in the example implementation 700 is similar to the example frontside process in the example implementation 400 in FIGS. 4A-4D, except that formation of the doped well region 268 is omitted in the frontside process in the example implementation 700. Instead, the doped well region 268 is subsequently formed after bonding of the semiconductor dies 202 and 204, as illustrated in the example implementations in FIGS. 8A-8D and 9A-9D.

Turning to FIG. 7A, one or more of the operations in the example implementation 700 may be performed in connection with the substrate layer 244 of the device layer 240 of the semiconductor die 204. The substrate layer 244 may be provided in the form of a semiconductor wafer (e.g., a silicon wafer), an SOI wafer, or another type of semiconductor substrate.

As shown in FIG. 7B, the integrated circuit devices 246 may be formed in and/or on the frontside of the substrate layer 244 of the device layer 240. Moreover, the reset gates 112, the source-follower gates 116 (not shown), and/or the row-select gates 118 (not shown) of the pixel sensors 100 may be formed in and/or on the substrate layer 244. The integrated circuit devices 246, the reset gates 112, the source-follower gates 116, and/or the row-select gates 118 may be formed using similar processing techniques and operations as described in connection with FIG. 4B.

As further shown in FIG. 7B, an STI region 264 may be formed in frontside of the substrate layer 244 such that the STI region 264 is located in the frontside of the substrate layer 244. The STI region 264 may be formed using similar processing techniques and operations as described in connection with FIG. 4B.

As shown in FIG. 7C, the interconnect layer 242 of the semiconductor die 204 may be formed above the frontside of the substrate layer 244 of the semiconductor die 204. The dielectric region 248 and the conductive structures 250 may be formed using similar processing techniques and operations as described in connection with FIG. 4C.

As shown in FIG. 7D, the bonding vias 254 may be formed on one or more conductive structures 250 in the interconnect layer 242, and bonding pads 252 may be formed above and/or on the bonding vias 254.

As indicated above, FIGS. 7A-7D are provided as an example. Other examples may differ from what is described with regard to FIGS. 7A-7D.

FIGS. 8A-8D are diagrams of an example implementation 800 of forming the semiconductor die package 200 (or a portion thereof) described herein. For example, the example implementation 800 may include an example of bonding the semiconductor dies 202 and 204 of the semiconductor die package 200, and performing backside processing on the semiconductor die 204 after bonding. The example implementation 800 includes an alternative to the backside processing implementation for the semiconductor die 204 in FIGS. 5A-5D. The example implementation 800 of backside processing for the semiconductor die 204 may be performed after the example implementation 700 of frontside processing for the semiconductor die 204, such that the doped well region 268 is formed in the substrate layer 244 during backside processing for the semiconductor die 204 after the semiconductor die 202 and the semiconductor die 204 are bonded at the bonding interface 208a.

As shown in FIG. 8A, a bonding operation is performed to bond the semiconductor die 202 and the semiconductor die 204 at the bonding interface 208a such that the semiconductor die 202 and the semiconductor die 204 are vertically arranged or stacked in the semiconductor die package 200. The semiconductor die 202 and the semiconductor die 204 may be bonded at the bonding interface 208a prior to the doped well region 268 being formed in the substrate layer 244. The semiconductor die 202 and the semiconductor die 204 may be bonded in a similar manner as described in connection with FIG. 5A.

As shown in FIGS. 8B and 8C, backside processing may be performed on the backside of the semiconductor die 204 after the semiconductor dies 202 and 204 are bonded at the bonding interface 208a. The backside processing may include forming the doped well region 268 in the substrate layer 244 (as shown in FIG. 8B), and forming the elongated conductive structure 262 (e.g., a TSV) through the doped well region 268 in the substrate layer 244 of the semiconductor die 204 (as shown in FIG. 8C).

The doped well region 268 may be formed in a similar manner as described in connection with FIG. 4A, except that the doped well region 268 is formed from the backside of the substrate layer 244 in the example implementation 800. For example, an ion implantation tool may be used to implant ions (e.g., n-type ions, p-type ions) into the substrate layer 244 from the backside of the substrate layer 244 to form the doped well region 268. As another example, a diffusion tool may be used to perform a diffusion operation in which dopants are diffused into the substrate layer 244 from the backside of the substrate layer 244. In some implementations, the doped well region 268 fully extends from the backside to the front of the substrate layer 244 such that the doped well region 268 is formed over and around the STI region 264. In some implementations, the doped well region 268 extends into a portion from the backside of the substrate layer 244. The doped well region 268 is formed over and around the source/drain region 288a of the reset gate 112 such that the doped well region 268 and the source/drain region 288a of the reset gate 112 are electrically connected.

The elongated conductive structure 262 may be formed through the doped well region 268 in a similar manner as described in connection with FIG. 5B. The elongated conductive structure 262 may be formed through the doped well region 268 in the substrate layer 244 adjacent to the reset gate 112. In this way, the doped well region 268 may laterally surround the elongated conductive structure 262. Formation of the elongated conductive structure 262 through the doped well region 268 results in formation of a series capacitance connection of capacitors 120 and 122 through the doped well region 268.

As shown in FIG. 8D, the interconnect layer 256 of the semiconductor die 204 may be formed above the backside of the substrate layer 244 of the semiconductor die 204. The dielectric region 258 and the conductive structures 260 of the interconnect layer 256 may be formed in a similar manner as described in connection with FIG. 5C.

As further shown in FIG. 8D, the bonding vias 272 may be formed on one or more conductive structures 260 in the interconnect layer 256, and bonding pads 270 may be formed above and/or on the bonding vias 272.

As indicated above, FIGS. 8A-8D are provided as an example. Other examples may differ from what is described with regard to FIGS. 8A-8D.

FIGS. 9A-9D are diagrams of an example implementation 900 of forming the semiconductor die package 200 (or a portion thereof) described herein. For example, the example implementation 900 may include an example of bonding the semiconductor dies 202 and 204 of the semiconductor die package 200, and performing backside processing on the semiconductor die 204 after bonding. The example implementation 900 includes an alternative to the backside processing implementation for the semiconductor die 204 in FIGS. 5A-5D. The example implementation 900 of backside processing for the semiconductor die 204 may be performed after the example implementation 700 of frontside processing for the semiconductor die 204, such that the doped well region 268 is formed in the substrate layer 244 during backside processing for the semiconductor die 204 after the semiconductor die 202 and the semiconductor die 204 are bonded at the bonding interface 208a.

As shown in FIG. 9A, a bonding operation is performed to bond the semiconductor die 202 and the semiconductor die 204 at the bonding interface 208a such that the semiconductor die 202 and the semiconductor die 204 are vertically arranged or stacked in the semiconductor die package 200. The semiconductor die 202 and the semiconductor die 204 may be bonded at the bonding interface 208a prior to the doped well region 268 being formed in the substrate layer 244. The semiconductor die 202 and the semiconductor die 204 may be bonded in a similar manner as described in connection with FIG. 5A.

As shown in FIGS. 9B and 9C, backside processing may be performed on the backside of the semiconductor die 204 after the semiconductor dies 202 and 204 are bonded at the bonding interface 208a. The backside processing may include forming the forming the elongated conductive structure 262 (e.g., a TSV) through the substrate layer 244 of the semiconductor die 204 (as shown in FIG. 9B), and forming the doped well region 268 around the elongated conductive structure 262 in the substrate layer 244 (as shown in FIG. 9C). Forming the doped well region 268 after formation of the STI region 264 and after formation of the elongated conductive structure 262 may result in the least amount of etching damage to the doped well region 268, which may enable the lowest amount of current leakage in the doped well region 268 (e.g., because of the least amount of dangling bonds that are formed in the doped well region 268).

The elongated conductive structure 262 may be formed through the doped well region 268 in a similar manner as described in connection with FIG. 5B. The elongated conductive structure 262 may be formed through the substrate layer 244 adjacent to the reset gate 112. The doped well region 268 may be formed in a similar manner as described in connection with FIG. 4A, except that the doped well region 268 is formed from the backside of the substrate layer 244, and formed around the elongated conductive structure 262 in the example implementation 900. For example, an ion implantation tool may be used to implant ions (e.g., n-type ions, p-type ions) around the elongated conductive structure 262 into the substrate layer 244 from the backside of the substrate layer 244 to form the doped well region 268. As another example, a diffusion tool may be used to perform a diffusion operation in which dopants are diffused into the substrate layer 244 from the backside of the substrate layer 244. In some implementations, the doped well region 268 fully extends from the backside to the front of the substrate layer 244 such that the doped well region 268 is formed over and around the STI region 264. In some implementations, the doped well region 268 extends into a portion from the backside of the substrate layer 244. The doped well region 268 is formed over and around the source/drain region 288a of the reset gate 112 such that the doped well region 268 and the source/drain region 288a of the reset gate 112 are electrically connected. In this way, the doped well region 268 may laterally surround the elongated conductive structure 262 and may be electrically connected with the source/drain region 288a, resulting in formation of a series capacitance connection of capacitors 120 and 122 through the doped well region 268.

As shown in FIG. 9D, the interconnect layer 256 of the semiconductor die 204 may be formed above the backside of the substrate layer 244 of the semiconductor die 204. The dielectric region 258 and the conductive structures 260 of the interconnect layer 256 may be formed in a similar manner as described in connection with FIG. 5C.

As further shown in FIG. 9D, the bonding vias 272 may be formed on one or more conductive structures 260 in the interconnect layer 256, and bonding pads 270 may be formed above and/or on the bonding vias 272.

As indicated above, FIGS. 9A-9D are provided as an example. Other examples may differ from what is described with regard to FIGS. 9A-9D.

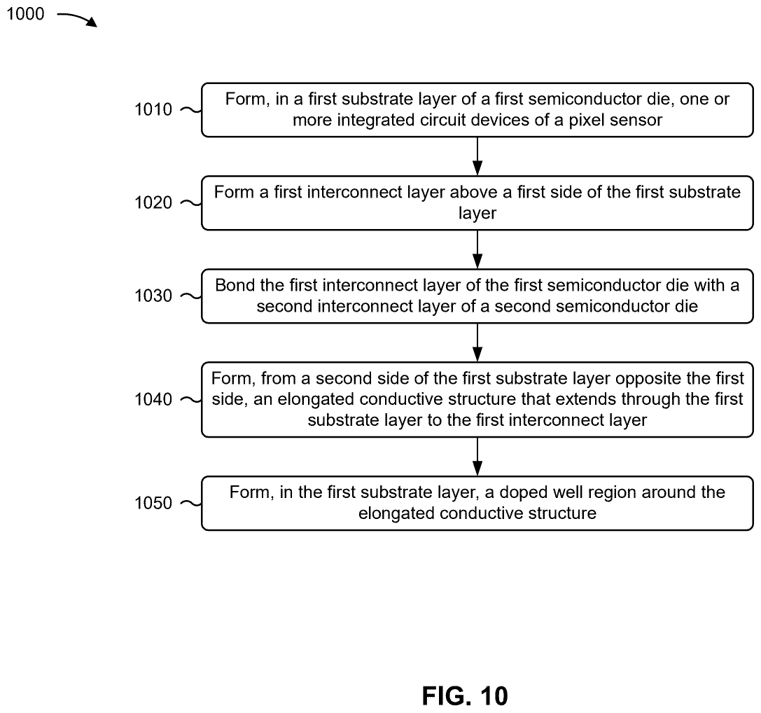

FIG. 10 is a flowchart of an example process 1000 associated with forming an image sensor device described herein. In some implementations, one or more process blocks of FIG. 10 are performed using one or more semiconductor processing tools, such as a deposition tool, an exposure tool, a developer tool, an etch tool, a planarization tool, an ion implantation tool, a bonding tool, a wafer/die transport tool, and/or another type of semiconductor processing tool.

As shown in FIG. 10, process 1000 may include forming, in a first substrate layer of a first semiconductor die, one or more integrated circuit devices of a pixel sensor (block 1010). For example, one or more semiconductor processing tools may be used to form, in a first substrate layer (e.g., a substrate layer 244) of a first semiconductor die (e.g., a semiconductor die 204), one or more integrated circuit devices (e.g., a reset gate 112, a source-follower gate 116, a row-select gate 118) of a pixel sensor (e.g., a pixel sensor 100), as described herein.

As further shown in FIG. 10, process 1000 may include forming a first interconnect layer above a first side of the first substrate layer (block 1020). For example, one or more semiconductor processing tools may be used to form a first interconnect layer (e.g., an interconnect layer 242) above a first side of the first substrate layer, as described herein.

As further shown in FIG. 10, process 1000 may include bonding the first interconnect layer of the first semiconductor die with a second interconnect layer of a second semiconductor die (block 1030). For example, one or more semiconductor processing tools may be used to bond the first interconnect layer of the first semiconductor die with a second interconnect layer (e.g., an interconnect layer 230) of a second semiconductor die (e.g., a semiconductor die 202), as described herein. In some implementations, the second semiconductor die comprises a second substrate layer (e.g., a substrate layer 220) in which a sensing region (e.g., a sensing region 102) of the pixel sensor is included.

As further shown in FIG. 10, process 1000 may include forming, from a second side of the first substrate layer opposite the first side, an elongated conductive structure that extends through the first substrate layer to the first interconnect layer (block 1040). For example, one or more semiconductor processing tools may be used to form, from a second side of the first substrate layer opposite the first side, an elongated conductive structure (e.g., an elongated conductive structure 262) that extends through the first substrate layer to the first interconnect layer, as described herein.

As further shown in FIG. 10, process 1000 may include forming, in the first substrate layer, a doped well region around the elongated conductive structure (block 1050). For example, one or more semiconductor processing tools may be used to form, in the first substrate layer, a doped well region (e.g., a doped well region 268) around the elongated conductive structure, as described herein.

Process 1000 may include additional implementations, such as any single implementation or any combination of implementations described below and/or in connection with one or more other processes described elsewhere herein.

In a first implementation, forming the doped well region includes doping the first substrate layer from the second side of the first substrate layer.

In a second implementation, alone or in combination with the first implementation, the doped well region includes an n-doped well region.

In a third implementation, alone or in combination with one or more of the first and second implementations, forming the doped well region includes forming the doped well region after bonding the first interconnect layer of the first semiconductor die with the second interconnect layer of the second semiconductor die.

In a fourth implementation, alone or in combination with one or more of the first through third implementations, forming the one or more integrated circuit devices of the pixel sensor includes forming a reset transistor (e.g., a reset gate 112) of the pixel sensor, and forming the doped well region includes forming the doped well region such that a source/drain region (e.g., a source/drain region 288a) of the reset transistor is located in the doped well region.

In a fifth implementation, alone or in combination with one or more of the first through fourth implementations, a dopant concentration of the doped well region is less than a dopant concentration of the source/drain region.

In a sixth implementation, alone or in combination with one or more of the first through fifth implementations, forming the doped well region includes forming the doped well region such that a portion of the doped well region is located between the elongated conductive structure and the source/drain region.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

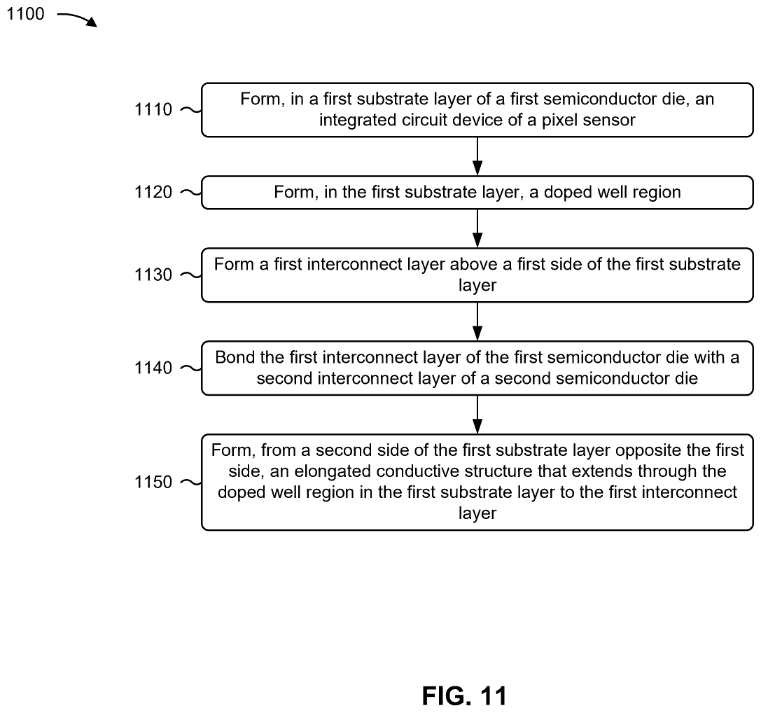

FIG. 11 is a flowchart of an example process 1100 associated with forming an image sensor device described herein. In some implementations, one or more process blocks of FIG. 11 are performed using one or more semiconductor processing tools, such as a deposition tool, an exposure tool, a developer tool, an etch tool, a planarization tool, an ion implantation tool, a bonding tool, a wafer/die transport tool, and/or another type of semiconductor processing tool.

As shown in FIG. 11, process 1100 may include forming, in a first substrate layer of a first semiconductor die, an integrated circuit device of a pixel sensor (block 1110). For example, one or more semiconductor processing tools may be used to form, in a first substrate layer (e.g., a substrate layer 244) of a first semiconductor die (e.g., a semiconductor die 204), an integrated circuit device (e.g., a reset gate 112) of a pixel sensor (e.g., a pixel sensor 100), as described herein.

As further shown in FIG. 11, process 1100 may include forming, in the first substrate layer, a doped well region (block 1120). For example, one or more semiconductor processing tools may be used to form, in the first substrate layer, a doped well region (e.g., a doped well region 268), as described herein. In some implementations, the doped well region is laterally adjacent to the integrated circuit device in the first substrate layer.

As further shown in FIG. 11, process 1100 may include forming a first interconnect layer above a first side of the first substrate layer (block 1130). For example, one or more semiconductor processing tools may be used to form a first interconnect layer (e.g., an interconnect layer 242) above a first side of the first substrate layer, as described herein.

As further shown in FIG. 11, process 1100 may include bonding the first interconnect layer of the first semiconductor die with a second interconnect layer of a second semiconductor die (block 1140). For example, one or more semiconductor processing tools may be used to bond the first interconnect layer of the first semiconductor die with a second interconnect layer (e.g., an interconnect layer 230) of a second semiconductor die (e.g., a semiconductor die 202), as described herein. In some implementations, the second semiconductor die includes a second substrate layer (e.g., a substrate layer 220) in which a sensing region (e.g., a sensing region 102) of the pixel sensor is included.

As further shown in FIG. 11, process 1100 may include forming, from a second side of the first substrate layer opposite the first side, an elongated conductive structure that extends through the doped well region in the first substrate layer to the first interconnect layer (block 1150). For example, one or more semiconductor processing tools may be used to form, from a second side of the first substrate layer opposite the first side, an elongated conductive structure (e.g., an elongated conductive structure 262) that extends through the doped well region in the first substrate layer to the first interconnect layer, as described herein.

Process 1100 may include additional implementations, such as any single implementation or any combination of implementations described below and/or in connection with one or more other processes described elsewhere herein.

In a first implementation, the doped well region laterally surrounds the elongated conductive structure.

In a second implementation, alone or in combination with the first implementation, forming the doped well region includes forming the doped well region prior to bonding the first interconnect layer of the first semiconductor die with the second interconnect layer of the second semiconductor die.

In a third implementation, alone or in combination with one or more of the first and second implementations, forming the doped well region includes doping the first substrate layer from the first side of the first substrate layer.

In a fourth implementation, alone or in combination with one or more of the first through third implementations, forming the doped well region includes forming the doped well region after bonding the first interconnect layer of the first semiconductor die with the second interconnect layer of the second semiconductor die.

In a fifth implementation, alone or in combination with one or more of the first through fourth implementations, forming the doped well region includes doping the first substrate layer from the second side of the first substrate layer.

In a sixth implementation, alone or in combination with one or more of the first through fifth implementations, the integrated circuit device includes a reset transistor (e.g., a reset gate 112) of the pixel sensor, and forming the doped well region includes forming the doped well region around a source/drain region (e.g., a source/drain region 288a) of the reset transistor in the first substrate layer.

In a seventh implementation, alone or in combination with one or more of the first through sixth implementations, the integrated circuit device includes a reset transistor (e.g., a reset gate 112) of the pixel sensor, and forming the integrated circuit device comprises forming a source/drain region (e.g., a source/drain region 288a) of the reset transistor in the doped well region.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a semiconductor die (e.g., an ASIC die) of an image sensor device (e.g., a CMOS image sensor device) includes a doped well region in a substrate layer of the semiconductor die. The doped well region may be included adjacent to an elongated conductive structure that extends vertically through the substrate layer into interconnect layers on opposing sides of the substrate layer. The doped well region introduces additional series capacitance between the elongated conductive structure and the substrate layer (which may be formed of one or more semiconductor materials). This additional series capacitance, which is electrically connected in series with parasitic capacitance associated with the elongated conductive structure, effectively reduces the overall parasitic capacitance in the control circuitry of the pixel sensors of the image sensor device. In this way, the reduced parasitic capacitance may enable a low RC delay to be achieved for the pixel sensors, which may increase the responsiveness of the pixel sensors. The increased responsiveness may increase the high-speed imaging performance and/or the low-light performance of the image sensor device, may increase the dynamic range of the image sensor device, and/or may reduce the power consumption of the image sensor device, among other examples.

As described in greater detail above, some implementations described herein provide a method. The method includes forming, in a first substrate layer of a first semiconductor die, one or more integrated circuit devices of a pixel sensor. The method includes forming a first interconnect layer above a first side of the first substrate layer. The method includes bonding the first interconnect layer of the first semiconductor die with a second interconnect layer of a second semiconductor die, where the second semiconductor die includes a second substrate layer in which a sensing region of the pixel sensor is included. The method includes forming, from a second side of the first substrate layer opposite the first side, an elongated conductive structure that extends through the first substrate layer to the first interconnect layer. The method includes forming, in the first substrate layer, a doped well region around the elongated conductive structure.

As described in greater detail above, some implementations described herein provide a method. The method includes forming, in a first substrate layer of a first semiconductor die, an integrated circuit device of a pixel sensor. The method includes forming, in the first substrate layer, a doped well region, where the doped well region is laterally adjacent to the integrated circuit device in the first substrate layer. The method includes forming a first interconnect layer above a first side of the first substrate layer. The method includes bonding the first interconnect layer of the first semiconductor die with a second interconnect layer of a second semiconductor die, where the second semiconductor die comprises a second substrate layer in which a sensing region of the pixel sensor is included. The method includes forming, from a second side of the first substrate layer opposite the first side, an elongated conductive structure that extends through the doped well region in the first substrate layer to the first interconnect layer.

As described in greater detail above, some implementations described herein provide an image sensor device. The image sensor device includes a first semiconductor die. The first semiconductor die includes a first substrate layer, a first interconnect layer vertically adjacent to a first side of the first substrate layer, and a pixel sensor array that includes a plurality of sensing regions on a second side of the first substrate layer opposing the first side. The image sensor device includes a second semiconductor die. The second semiconductor die includes a second substrate layer, a second interconnect layer, vertically adjacent to a first side of the second substrate layer, a third interconnect layer vertically adjacent to a second side of the second substrate layer opposing the first side, an elongated conductive structure extending through the second substrate layer, where a first end of the elongated conductive structure is located in the second interconnect layer, and where a second opposing end of the elongated conductive structure is located in the third interconnect layer, a doped well region around the elongated conductive structure, and a transistor structure in the second substrate layer, where the doped well region is between the transistor structure and the elongated conductive structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, in a first substrate layer of a first semiconductor die, one or more integrated circuit devices of a pixel sensor;
forming a first interconnect layer above a first side of the first substrate layer;
bonding the first interconnect layer of the first semiconductor die with a second interconnect layer of a second semiconductor die,
wherein the second semiconductor die comprises a second substrate layer in which a sensing region of the pixel sensor is included;
forming, from a second side of the first substrate layer opposite the first side, an elongated conductive structure that extends through the first substrate layer to the first interconnect layer; and
forming, in the first substrate layer, a doped well region around the elongated conductive structure.

2. The method of claim 1, wherein forming the doped well region comprises:
doping the first substrate layer from the second side of the first substrate layer.

3. The method of claim 1, wherein the doped well region comprises an n-doped well region.

4. The method of claim 1, wherein forming the doped well region comprises:
forming the doped well region after bonding the first interconnect layer of the first semiconductor die with the second interconnect layer of the second semiconductor die.

5. The method of claim 1, wherein forming the one or more integrated circuit devices of the pixel sensor comprises:
forming a reset transistor of the pixel sensor; and
wherein forming the doped well region comprises:
forming the doped well region such that a source/drain region of the reset transistor is located in the doped well region.

6. The method of claim 5, wherein a dopant concentration of the doped well region is less than a dopant concentration of the source/drain region.

7. The method of claim 5, wherein forming the doped well region comprises:
forming the doped well region such that a portion of the doped well region is located between the elongated conductive structure and the source/drain region.

8. A method, comprising:
forming, in a first substrate layer of a first semiconductor die, an integrated circuit device of a pixel sensor;
forming, in the first substrate layer, a doped well region,
wherein the doped well region is laterally adjacent to the integrated circuit device in the first substrate layer;
forming a first interconnect layer above a first side of the first substrate layer;
bonding the first interconnect layer of the first semiconductor die with a second interconnect layer of a second semiconductor die,
wherein the second semiconductor die comprises a second substrate layer in which a sensing region of the pixel sensor is included; and
forming, from a second side of the first substrate layer opposite the first side, an elongated conductive structure that extends through the doped well region in the first substrate layer to the first interconnect layer.

9. The method of claim 8, wherein the doped well region laterally surrounds the elongated conductive structure.

10. The method of claim 8, wherein forming the doped well region comprises:
forming the doped well region prior to bonding the first interconnect layer of the first semiconductor die with the second interconnect layer of the second semiconductor die.

11. The method of claim 10, wherein forming the doped well region comprises:
doping the first substrate layer from the first side of the first substrate layer.

12. The method of claim 8, wherein forming the doped well region comprises:
forming the doped well region after bonding the first interconnect layer of the first semiconductor die with the second interconnect layer of the second semiconductor die.

13. The method of claim 12, wherein forming the doped well region comprises:
doping the first substrate layer from the second side of the first substrate layer.

14. The method of claim 8, wherein the integrated circuit device comprises a reset transistor of the pixel sensor; and
wherein forming the doped well region comprises:
forming the doped well region around a source/drain region of the reset transistor in the first substrate layer.

15. The method of claim 8, wherein the integrated circuit device comprises a reset transistor of the pixel sensor; and
wherein forming the integrated circuit device comprises:
forming a source/drain region of the reset transistor in the doped well region.

16. An image sensor device, comprising:
a first semiconductor die, comprising:
a first substrate layer;
a first interconnect layer vertically adjacent to a first side of the first substrate layer; and
a pixel sensor array comprising a plurality of sensing regions on a second side of the first substrate layer opposing the first side; and
a second semiconductor die, comprising:
a second substrate layer;
a second interconnect layer vertically adjacent to a first side of the second substrate layer;
a third interconnect layer vertically adjacent to a second side of the second substrate layer opposing the first side;
an elongated conductive structure extending through the second substrate layer,
wherein a first end of the elongated conductive structure is located in the second interconnect layer, and
wherein a second opposing end of the elongated conductive structure is located in the third interconnect layer;
a doped well region around the elongated conductive structure; and
a transistor structure in the second substrate layer,
wherein the doped well region is between the transistor structure and the elongated conductive structure.

17. The image sensor device of claim 16, wherein the second semiconductor die further comprises:
a dielectric liner on a sidewall of the elongated conductive structure,
wherein the dielectric liner is laterally between the sidewall of the elongated conductive structure and the doped well region.

18. The image sensor device of claim 16, wherein the transistor structure comprises a source/drain region located in the doped well region; and
wherein a dopant concentration of the source/drain region is greater than a dopant concentration of the doped well region.

19. The image sensor device of claim 18, wherein the source/drain region and the doped well region both include a same dopant type.

20. The image sensor device of claim 16, wherein the second semiconductor die further comprises:
a shallow trench isolation (STI) region in the first side of the second substrate layer,
wherein the elongated conductive structure extends through the STI region, and
wherein the STI region is included in the doped well region in the second substrate layer.
